(19) United States
(12) Patent Application Publication
(10) Pub. No.: US 2025/0287810 A1
(43) Pub. Date: Sep. 11, 2025

(54) IMAGE DISPLAY APPARATUS

(71) Applicant: FUJIFILM Corporation, Tokyo (JP)

(72) Inventor: Yujiro YANAI, Kanagawa (JP)

(73) Assignee: FUJIFILM Corporation, Tokyo (JP)

(21) Appl. No.: 19/211,338

(22) Filed: May 19, 2025

Related U.S. Application Data
(63) Continuation of application No. PCT/JP2023/041444, filed on Nov. 17, 2023.

(30) Foreign Application Priority Data
Nov. 21, 2022 (JP) 2022-185539

(51) Int. Cl. H10K 59/65; H10F 39/00

(52) U.S. Cl. CPC H10K 59/65; H10F 39/806

(57) ABSTRACT

Provided is an image display apparatus capable of detecting the amount of light of each wavelength of the ambient light transmitted through the image display panel with high accuracy in an image display apparatus including an image display panel and an ambient light sensor system. An image display apparatus includes an image display panel and an ambient light sensor system, in which the image display panel includes a transmission unit that allows ambient light to pass through in a display region. The ambient light sensor system includes a diffraction grating that diffracts light of each wavelength component at different angles according to a wavelength of the ambient light that has passed through the transmission unit, and a light detection unit that receives the light diffracted by the diffraction grating.

### CROSS-REFERENCE TO RELATED APPLICATIONS

This application is a Continuation of PCT International Application No. PCT/JP2023/041444 filed on Nov. 17, 2023, which claims priority under 35 U.S.C. § 119(a) to Japanese Patent Application No. 2022-185539 filed on Nov. 21, 2022. The above applications are hereby expressly incorporated by reference, in their entirety, into the present application.

### BACKGROUND OF THE INVENTION

### 1. Field of the Invention

The present invention relates to an image display apparatus having an ambient light sensor system that detects ambient light.

### 2. Description of the Related Art

In the image display apparatus, an ambient light sensor that detects ambient brightness may be provided in order to control the brightness of display according to ambient brightness.

In such an image display apparatus, it is common that the ambient light sensor is disposed in a housing portion (frame portion) outside a display region. By the way, in order to increase the display region with respect to the size of the apparatus, it is desired that the image display apparatus is narrowed in a frame, and particularly, in a mobile device such as a smartphone and a tablet terminal, it is desired that the image display apparatus is narrowed in a frame in order to increase the display region while reducing the size of the apparatus. However, in a case where the device is narrowed in a frame, it is difficult to dispose the ambient light sensor in a housing portion outside the display region.

Therefore, it is considered to dispose the ambient light sensor on a back surface side (a side opposite to a display surface) of a display panel of the image display apparatus.

For example, in SID 2022 DIGEST P117-120 “Through-OLED Display Ambient Color Sensing”, an image display apparatus is described in which an ambient light sensor is disposed on a rear surface side of an organic light emitting diode (OLED) to measure ambient light transmitted through the OLED.

In addition, in SID 2022 DIGEST P117-120 “Through-OLED Display Ambient Color Sensing”, the color temperature of ambient light is measured by passing ambient light transmitted through OLED through a color filter and measuring the amount of light for each color.

### SUMMARY OF THE INVENTION

The amount of ambient light transmitted through an image display panel such as an OLED is very small. Further, in a case where the ambient light transmitted through the image display panel is passed through the color filter in order to measure the color temperature of the ambient light, light of each color (wavelength) is blocked by the color filter of another color, and thus the amount of light detected for each wavelength is reduced. Therefore, it is found that there is a problem that it is difficult to accurately detect the amount of light of each wavelength of the ambient light.

In addition, light emitted from an image display panel such as an OLED may not be emitted from the image display apparatus, but may be reflected by an interface or the like of each layer, and may be transmitted through the image display panel and detected by the ambient light sensor. Since such light becomes noise, it has been found that it is difficult to measure the amount of light at each wavelength of the ambient light with high accuracy.

An object of the present invention is to solve the above-described problem of the related art and to provide an image display apparatus capable of detecting the amount of light of each wavelength of the ambient light transmitted through the image display panel with high accuracy in an image display apparatus including an image display panel and an ambient light sensor system.

In order to accomplish the object, the present invention has the following configurations.

[1] An image display apparatus including: an image display panel; and an ambient light sensor system, in which the image display panel includes a transmission unit that allows ambient light to pass through in a display region, the ambient light sensor system includes a diffraction grating that diffracts light of each wavelength component at different angles according to a wavelength of the ambient light that has passed through the transmission unit, and a light detection unit that receives the light diffracted by the diffraction grating.

[2] The image display apparatus according to [1], in which the ambient light sensor system further includes a light guide plate.

[3] The image display apparatus according to [2], in which the diffraction grating includes an incidence-side diffraction grating for light incidence on the light guide plate and an emission-side diffraction grating for light emission from the light guide plate.

[4] The image display apparatus according to any one of [1] to [3], in which the diffraction grating is a transmissive diffraction grating.

[5] The image display apparatus according to any one of [1] to [3], in which the diffraction grating is a reflective diffraction grating.

[6] The image display apparatus according to any one of [1] to [5], in which the diffraction grating is any one of a liquid crystal diffraction element, a surface relief type diffraction element, or a metasurface.

[7] The image display apparatus according to any one of [1] to [6], in which the light detection unit has a plurality of photoelectric conversion elements arranged, and each photoelectric conversion element detects an amount of light of each wavelength component diffracted at different angles.

[8] The image display apparatus according to any one of [1] to [7], in which the light detection unit includes a line sensor, and each pixel of the line sensor detects an amount of light of each wavelength component diffracted at different angles.

[9] The image display apparatus according to any one of [1] to [8], further including: at least one of a lens, a prism, a louver, a phase difference plate, or an anisotropic light absorbing layer that is disposed on the transmission unit or at least one of the transmission unit or the diffraction grating.

According to the present invention, it is possible to solve the above-described problem of the related art, and it is possible to provide an image display apparatus capable of detecting the amount of light of each wavelength of the ambient light transmitted through the image display panel with high accuracy in an image display apparatus including an image display panel and an ambient light sensor system.

### BRIEF DESCRIPTION OF THE DRAWINGS

FIG. 1 is a front view conceptually showing an example of an image display apparatus of the present invention.

FIG. 2 is a cross-sectional view taken along line A-A of FIG. 1.

FIG. 3 is a cross-sectional view conceptually showing another example of the image display apparatus according to the present invention.

FIG. 4 is a cross-sectional view conceptually showing another example of the image display apparatus according to the present invention.

FIG. 5 is a cross-sectional view conceptually showing another example of the image display apparatus according to the present invention.

FIG. 6 is a cross-sectional view conceptually showing another example of the image display apparatus according to the present invention.

FIG. 7 is a cross-sectional view conceptually showing another example of the image display apparatus according to the present invention.

FIG. 8 is a cross-sectional view conceptually showing another example of the image display apparatus according to the present invention.

FIG. 9 is a cross-sectional view conceptually showing another example of the image display apparatus according to the present invention.

FIG. 10 is a cross-sectional view conceptually showing another example of the image display apparatus according to the present invention.

FIG. 11 is a cross-sectional view conceptually showing another example of the image display apparatus according to the present invention.

FIG. 12 is a diagram conceptually showing an example of a liquid crystal diffraction element that is used as a transmissive diffraction grating.

FIG. 13 is a plan view showing the liquid crystal diffraction element shown in FIG. 12.

FIG. 14 is a conceptual view showing an action of the liquid crystal diffraction element shown in FIG. 12.

FIG. 15 is a conceptual view showing an action of the liquid crystal diffraction element shown in FIG. 12.

FIG. 16 is a diagram conceptually showing an example of a liquid crystal diffraction element that is used as a reflective diffraction grating.

FIG. 17 is a diagram showing the action of the liquid crystal diffraction element shown in FIG. 16.

FIG. 18 is a view conceptually showing an example of an exposure device which exposes an alignment film.

FIG. 19 is a conceptual view for describing a configuration of an example.

FIG. 20 is a conceptual view for describing a configuration of a Comparative Example.

FIG. 21 is a conceptual view for describing a configuration of a Comparative Example.

### DESCRIPTION OF THE PREFERRED EMBODIMENTS

Hereinafter, an image display apparatus according to an embodiment of the present invention will be described in detail based on suitable embodiment illustrated in the accompanying drawings.

In the present specification, numerical ranges represented by “to” include numerical values before and after “to” as lower limit values and upper limit values.

In the present specification, “(meth)acrylate” is used to mean “either or both of acrylate and methacrylate”.

In the present specification, visible light is light having a wavelength which can be seen by human eyes among electromagnetic waves, and refers to light in a wavelength range of 380 to 780 nm. Non-visible light refers to light in a wavelength range of less than 380 nm or more than 780 nm.

In the present specification, Re(λ) represents an in-plane retardation at a wavelength λ. Unless otherwise specified, the wavelength λ is 550 nm.

In the present specification, Re(λ) is a value measured at the wavelength λ using AxoScan (manufactured by Axometrics, Inc.). By inputting an average refractive index ((nx+ny+nz)/3) and a film thickness (d (μm)) to AxoScan, the following expression can be calculated.

Slow axis direction (°)

Re(λ)=R0(λ)
R0(λ) is expressed as a numerical value calculated by AxoScan and represents Re(λ).

### [Image Display Apparatus]

The image display apparatus according to the embodiment of the present invention is an image display apparatus including an image display panel and an ambient light sensor system, in which the image display panel includes a transmission unit that allows ambient light to pass through in a display region, the ambient light sensor system includes a diffraction grating that diffracts light of each wavelength component at different angles according to a wavelength of the ambient light that has passed through the transmission unit, and a light detection unit that receives the light diffracted by the diffraction grating.

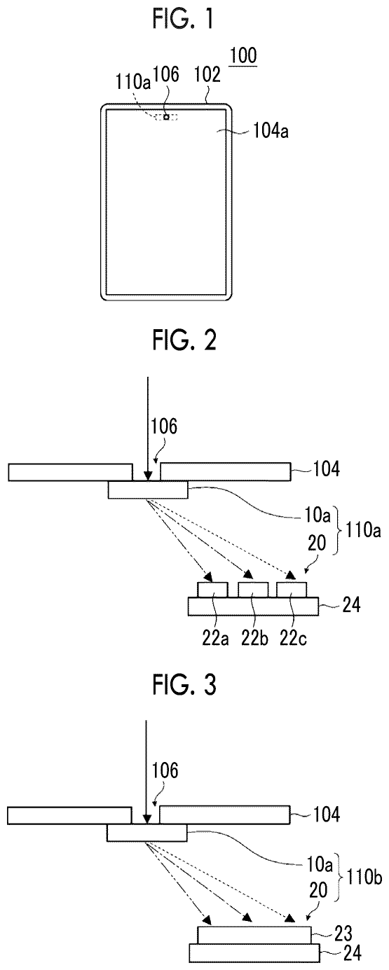

FIG. 1 is a front view conceptually showing an example of an image display apparatus according to the embodiment of the present invention. FIG. 2 is an enlarged view of a part of the cross section taken along the line A-A of FIG. 1.

An image display apparatus 100 shown in FIGS. 1 and 2 has a housing 102, an image display panel 104, and an ambient light sensor system 110a having a transmissive diffraction grating 10a and a light detection unit 20. In the example shown in the drawing, the image display apparatus 100 is an image display apparatus included in a smartphone.

The housing 102 is a member that houses the image display panel 104, the ambient light sensor system 110a, and the like. As the housing 102, a housing according to a device configuration including the image display apparatus 100 may be used. That is, in the illustrated example, since the image display apparatus 100 is an image display apparatus included in the smartphone, the housing 102 may be a housing of the smartphone.

The image display panel 104 is basically a known image display panel (display). Examples of the image display panel include a liquid crystal display panel, an organic electroluminescent display device, a light emitting diode (LED) display device, and a micro LED display device. In the following description, the organic electroluminescent display device will also be referred to as “OLED”. OLED is an abbreviation for “Organic Light Emitting Diode”.

Here, in the present invention, the image display panel 104 has a transmission unit 106 that allows transmission of ambient light from a display surface 104a side to a back surface side in the display surface 104a on which the image is displayed.

The transmission unit 106 may have a configuration in which a region capable of transmitting light without having pixels is provided in a part of the image display panel 104, or the image display panel 104 itself may have a configuration in which light can be transmitted from a region between pixels.

The transmission unit 106 may be formed at any position in the display surface 104a of the image display panel 104.

From the viewpoint of ensuring the amount of transmitted light while making the transmission unit 106 difficult to be visually recognized, the size of the region where the transmission unit 106 is provided as the transmissive region is preferably 4.0 mm² or less, more preferably 1.0 mm² or more and 3.5 mm² or less, and still more preferably 1.5 mm² or more and 3.0 mm² or less.

In a case where the image display panel 104 itself is configured to be capable of transmitting ambient light, the transmittance of the ambient light is about 0.5% to 3.0%. Even in a case where the transmittance of the ambient light of the image display panel 104 is low as described above, the image display apparatus according to the embodiment of the present invention can detect the amount of light of each wavelength of the ambient light with high accuracy.

The ambient light sensor system 110a is a portion that detects the luminance and the color temperature of the ambient light from the ambient light transmitted through the transmission unit 106 of the image display panel 104. The ambient light sensor system 110a is disposed on a back surface side of the image display panel 104 (a surface side opposite to the display surface 104a).

As shown in FIG. 2, an ambient light sensor system 110a includes a transmissive diffraction grating 10a and a light detection unit 20.

The transmissive diffraction grating 10a is disposed at a position overlapping with the transmission unit 106 in a case of being viewed from a direction perpendicular to the display surface 104a of the image display panel 104. The transmissive diffraction grating 10a transmits and diffracts the ambient light incident through the transmission unit 106 at different angles for each wavelength component of the light, according to the wavelength of the ambient light. In the example shown in FIG. 2, the red light (broken line arrow), the green light (one-dot chain line arrow), and the blue light (two-dot chain line arrow) are diffracted at different angles. The transmissive diffraction grating 10a diffracts light of each wavelength component at different angles, but the azimuth directions of diffraction are substantially the same.

As the transmissive diffraction grating 10a, a known diffraction element that can transmit incident light, diffract the transmitted light, and diffract the transmitted light at different angles depending on wavelengths, such as a liquid crystal diffraction element, a surface relief type diffraction element, and a metasurface, can be used. Such a diffraction element will be described in detail later.

The light detection unit 20 is a portion that detects the amount of light diffracted by the transmissive diffraction grating 10a at different angles for each wavelength. In the example shown in FIG. 2, the light detection unit 20 includes three photoelectric conversion elements 22a to 22c arranged in one direction and a support member 24 that supports the photoelectric conversion elements 22a to 22c.

The light detection unit 20 is disposed at a position spaced apart from the transmissive diffraction grating 10a in a direction perpendicular to the display surface 104a of the image display panel 104. In addition, in a case where the light detection unit 20 is viewed in a direction perpendicular to the display surface 104a, the light detection unit 20 is disposed at a position that does not overlap with the transmission unit 106, and is disposed such that each wavelength component diffracted by the transmissive diffraction grating 10a is incident on each of the photoelectric conversion elements 22a to 22c. That is, in the example shown in FIG. 2, the photoelectric conversion elements 22a, 22b, and 22c are disposed such that the blue light (two-dot chain line arrow) is incident on the photoelectric conversion element 22a, the green light (one-dot chain line arrow) is incident on the photoelectric conversion element 22b, and the red light (broken line arrow) is incident on the photoelectric conversion element 22c. Accordingly, in a case where the photoelectric conversion elements 22a to 22c are viewed in a direction perpendicular to the display surface 104a, the photoelectric conversion elements 22a to 22c are arranged in one direction, and the one direction and the azimuth direction of diffraction by the transmissive diffraction grating 10a match each other.

As the photoelectric conversion elements 22a to 22c, known photoelectric conversion elements such as a photodiode and a phototransistor that output a current in accordance with the received amount of light can be appropriately used.

In addition, the support member 24 is a portion that supports the photoelectric conversion elements 22a to 22c to be arranged in one direction. The support member 24 may be a wiring board provided with a wiring line or the like for driving the photoelectric conversion elements 22a to 22c. The support member 24 may be provided with an amplification circuit, an analog-to-digital (AD) converter, and the like for signals output from the photoelectric conversion elements 22a to 22c, respectively.

The size of each of the photoelectric conversion elements 22a to 22c is not limited as long as the wavelength components diffracted and separated by the transmissive diffraction grating 10a at different angles can be received (detected). However, it is preferable to increase the area and increase the incidence angle from the viewpoint that high detection sensitivity can be obtained.

In such a manner, the ambient light sensor system 110a diffracts the ambient light transmitted through the transmission unit 106 at different angles for each wavelength component by the transmissive diffraction grating 10a, and detects the amount of light for each diffracted wavelength component by the plurality of photoelectric conversion elements 22a to 22c. Accordingly, the brightness (luminance) and the color temperature of the ambient light can be measured.

As described above, in the image display apparatus in the related art, in a case where the display region is narrowed to be larger, it is difficult to dispose the ambient light sensor in a housing portion (frame portion) outside the display region. Therefore, it is considered to dispose the ambient light sensor on a back surface side (a side opposite to the display surface) of the display panel. However, according to the study of the present inventor, in a case where the ambient light is passed through the color filter to measure the amount of light for each color in a case where the color temperature of the ambient light is measured, the light of each color (wavelength) is blocked by the color filter of another color. Therefore, the total amount of light for each detected wavelength is reduced. That is, only a part of the ambient light transmitted through the display panel was used for the detection, and the remaining components could not be used. For example, in a case where each of three colors of RGB is detected, only ⅓ of the amount of light of each color component transmitted through the display panel can be used, and the remaining ⅔ of the amount of light is blocked by a color filter of another color. Therefore, it is found that there is a problem that it is difficult to accurately detect the amount of light of each wavelength of the ambient light. In addition, it was found that there is a problem in that, in a case where light emitted from the image display panel is reflected by an interface or the like of each layer without being emitted from the image display apparatus, the light is transmitted through the image display panel and is detected by the ambient light sensor, and thus the light is noise, and it is difficult to measure the amount of light of each wavelength of ambient light with high accuracy.

On the other hand, in the image display apparatus according to the embodiment of the present invention, the ambient light transmitted through the transmission unit 106 is diffracted by the transmissive diffraction grating 10a at different angles for each wavelength component. Therefore, almost all of the wavelength components of the ambient light transmitted through the transmission unit 106 can be used for detection, and the amount of light of each wavelength component incident on the light detection unit 20 can be increased. Therefore, the amount of light at each wavelength of the ambient light can be detected with high accuracy. In addition, in the image display apparatus according to the embodiment of the present invention, the ambient light transmitted through the transmission unit 106 is diffracted by the transmissive diffraction grating 10a. A direction in which light is diffracted by the transmissive diffraction grating 10a changes depending on an incidence angle of light into the transmissive diffraction grating 10a. In addition, as shown in FIG. 2, the ambient light sensor system 110a is configured to diffract each wavelength component of ambient light incident from a direction substantially perpendicular to the display surface 104a at an angle at which the component is incident on the light detection unit 20 (photoelectric conversion element). On the other hand, in a case where the noise light emitted from the image display panel and reflected by the interface or the like of each layer is incident into the transmissive diffraction grating 10a, since the noise light is incident on the transmissive diffraction grating 10a from an oblique direction, the noise light incident from the oblique direction is diffracted in a direction different from the direction (angle) of the light detection unit 20 (photoelectric conversion element). Therefore, the transmissive diffraction grating 10a can suppress the detection of the noise light by the light detection unit 20. Accordingly, the amount of light at each wavelength of the ambient light can be measured with high accuracy.

In the example shown in FIG. 2, the transmissive diffraction grating 10a is shown as a diffraction grating that diffracts incident ambient light into three components according to wavelengths at different angles. However, the change in diffraction angle of the transmissive diffraction grating 10a may be a continuous change with respect to a change in wavelength.

In addition, in the example shown in FIG. 2, the light detection unit 20 has a configuration in which three photoelectric conversion elements 22a to 22c are provided and detects light in three different wavelength ranges (colors), but the present invention is not limited to this, and a configuration in which two photoelectric conversion elements are provided may be adopted, or a configuration in which four or more photoelectric conversion elements are provided may be adopted.

In addition, in the example shown in FIG. 2, the light detection unit 20 has a configuration in which a plurality of photoelectric conversion elements are arranged, but the present invention is not limited to this. As in the example shown in FIG. 3, the light detection unit 20 may have a configuration in which a line sensor 23 is provided instead of the plurality of photoelectric conversion elements. The line sensor is an imaging element in which a plurality of pixels are arranged one-dimensionally (linearly), and a known imaging element such as a charge-coupled device (CCD) image sensor or a complementary metal oxide semiconductor (CMOS) image sensor can be used. In addition, a two-dimensional sensor in which a plurality of pixels are two-dimensionally arranged may be used.

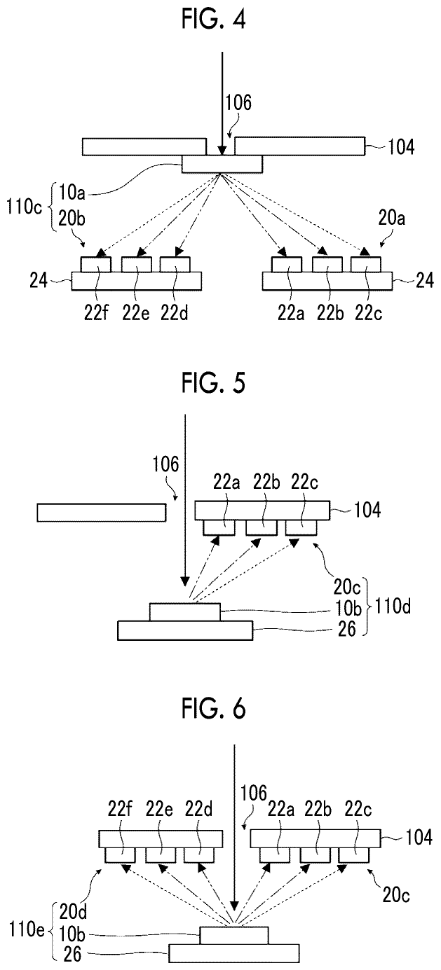

In FIG. 3, the same parts as those in the example shown in FIG. 2 are denoted by the same reference numerals, and the description thereof will be omitted. The same applies to FIGS. 4 to 11.

In addition, as will be described in detail later, in a case where the liquid crystal diffraction element is used as the transmissive diffraction grating 10a, the liquid crystal diffraction element diffracts the incident ambient light in an opposite azimuth direction according to the polarization state thereof. Specifically, the liquid crystal diffraction element diffracts dextrorotatory circularly polarized light and levorotatory circularly polarized light in different azimuth directions by 180°. Therefore, in a case where the ambient light transmitted through the transmission unit 106 is unpolarized light and is incident into the transmissive diffraction grating 10a, the dextrorotatory circularly polarized light component and the levorotatory circularly polarized light component of the incident ambient light are diffracted in opposite azimuth directions.

In a case where the liquid crystal diffraction element is used as the transmissive diffraction grating 10a and the ambient light as unpolarized light is incident on the liquid crystal diffraction element, as in the example shown in FIG. 4, the ambient light sensor system 110c may have a configuration in which two light detection units including a light detection unit 20a that detects each wavelength component of a dextrorotatory circularly polarized light component and a light detection unit 20b that detects each wavelength component of a levorotatory circularly polarized light component of the incident ambient light are provided.

In the example shown in FIG. 4, the transmissive diffraction grating 10a diffracts one polarized light component in the azimuth direction to the right in the drawing and diffracts the other polarized light component in the azimuth direction to the left in the drawing, and the two light detection units are arranged side by side in the left-right direction. In the example shown in FIG. 4, the photoelectric conversion elements 22a, 22b, and 22c are disposed such that in the ambient light diffracted by the transmissive diffraction grating 10a, blue light (two-dot chain line arrow) of the one polarized light component is incident on the photoelectric conversion element 22a of the light detection unit 20a, green light (one-dot chain line arrow) is incident on the photoelectric conversion element 22b, and red light (broken line arrow) is incident on the photoelectric conversion element 22c. In addition, the photoelectric conversion elements 22a, 22b, and 22c are disposed such that in the ambient light diffracted by the transmissive diffraction grating 10a, blue light (two-dot chain line arrow) of the other polarized light component is incident on the photoelectric conversion element 22d of the light detection unit 20b, green light (one-dot chain line arrow) is incident on the photoelectric conversion element 22e, and red light (broken line arrow) is incident on the photoelectric conversion element 22f.

In this way, in a case where the transmissive diffraction grating 10a diffracts the incidence ambient light in the opposite azimuth direction according to the polarization state, the amount of light of each wavelength component to be detected can be increased by the configuration in which the light in each polarization state is detected. Therefore, the amount of light at each wavelength of the ambient light can be detected with high accuracy.

Here, in the example shown in FIG. 2 and the like, the configuration is adopted in which the transmissive diffraction grating is used as the diffraction grating, but the present invention is not limited to this, and the reflective diffraction grating may be used as the diffraction grating. The reflective diffraction grating diffracts incident light in a direction different from specular reflection.

FIG. 5 is a cross-sectional view conceptually showing another example of the image display apparatus according to the embodiment of the present invention.

The image display apparatus shown in FIG. 5 includes an image display panel 104 and an ambient light sensor system 110d. Although not shown, the image display apparatus shown in FIG. 5 may have other members such as a housing.

The ambient light sensor system 110d includes a reflective diffraction grating 10b and a light detection unit 20c.

The reflective diffraction grating 10b is disposed at a position overlapping with the transmission unit 106 in a case of being viewed from a direction perpendicular to the display surface 104a of the image display panel 104. In addition, the reflective diffraction grating 10b is disposed to be spaced apart from the image display panel 104 in a direction perpendicular to the display surface 104a. In the example shown in the drawing, the reflective diffraction grating 10b is disposed on the support member 26. The reflective diffraction grating 10b diffracts and reflects the ambient light incident through the transmission unit 106 at different angles for each wavelength component of the light, according to the wavelength of the ambient light. In the example shown in FIG. 5, the red light (broken line arrow), the green light (one-dot-chain line arrow), and the blue light (two-dot chain line arrow) are diffracted at different angles. The reflective diffraction grating 10b diffracts and reflects light of each wavelength component at different angles, but the azimuth directions of diffraction are substantially the same.

As the reflective diffraction grating 10b, a known diffraction element that is capable of diffracting incident light while reflecting the light and diffracting the light at different angles depending on the wavelength, such as a liquid crystal diffraction element, a surface relief type diffraction element, and a metasurface, can be used. Such a diffraction element will be described in detail later.

The light detection unit 20c is a portion that detects the amount of light diffracted by the reflective diffraction grating 10b at different angles for each wavelength. In the example shown in FIG. 5, the light detection unit 20c has three photoelectric conversion elements 22a to 22c arranged in one direction. In addition, the three photoelectric conversion elements 22a to 22c are disposed such that the light-receiving surfaces thereof are opposite to the image display panel 104 side.

In the example shown in FIG. 5, the three photoelectric conversion elements 22a to 22c are disposed on the back surface side of the image display panel 104.

In the example shown in FIG. 5, the three photoelectric conversion elements 22a to 22c are disposed on the back surface side of the image display panel 104 via an adhesive or the like.

In a case where the light detection unit 20c is viewed in a direction perpendicular to the display surface 104a, the light detection unit 20c is disposed at a position that does not overlap with the transmission unit 106, and is disposed such that each wavelength component reflected and diffracted by the reflective diffraction grating 10b is incident on each of the photoelectric conversion elements 22a to 22c. That is, in the example shown in FIG. 5, the photoelectric conversion elements 22a, 22b, and 22c are disposed such that the blue light (two-dot chain line arrow) is incident on the photoelectric conversion element 22a, the green light (one-dot chain line arrow) is incident on the photoelectric conversion element 22b, and the red light (broken line arrow) is incident on the photoelectric conversion element 22c. Accordingly, in a case where the photoelectric conversion elements 22a to 22c are viewed in a direction perpendicular to the display surface 104a, the photoelectric conversion elements 22a to 22c are arranged in one direction, and the one direction and the azimuth direction of diffraction by the reflective diffraction grating 10b match each other.

In such a manner, the ambient light sensor system 110d reflects and diffracts the ambient light transmitted through the transmission unit 106 at different angles for each wavelength component by the reflective diffraction grating 10b, and detects the amount of light for each diffracted wavelength component by the plurality of photoelectric conversion elements 22a to 22c. Accordingly, the brightness (luminance) and the color temperature of the ambient light can be measured. In this case, the ambient light transmitted through the transmission unit 106 is diffracted by the reflective diffraction grating 10b at different angles for each wavelength component. Therefore, almost all of the wavelength components of the ambient light transmitted through the transmission unit 106 can be used for detection, and the amount of light of each wavelength component incident on the light detection unit 20c can be increased. Therefore, the amount of light at each wavelength of the ambient light can be detected with high accuracy. In addition, since the reflective diffraction grating 10b diffracts the noise light incident from the oblique direction in a direction (angle) different from the direction (angle) of the light detection unit 20c (photoelectric conversion element), it is possible to suppress the detection of the noise light by the light detection unit 20c. Accordingly, the amount of light at each wavelength of the ambient light can be measured with high accuracy.

In addition, in the example shown in FIG. 5, the photoelectric conversion elements 22a to 22c are disposed such that the light-receiving surfaces thereof are opposite to the image display panel 104 side. Therefore, it is possible to suppress the noise light incident from the transmission unit 106 from being incident on the photoelectric conversion elements 22a to 22c, and it is possible to measure the amount of light of each wavelength of the ambient light with higher accuracy.

In the example shown in FIG. 5, the reflective diffraction grating 10b is shown as a diffraction grating that diffracts incident ambient light into three components according to wavelengths at different angles. However, the change in diffraction angle of the reflective diffraction grating 10b may be a continuous change with respect to a change in wavelength.

In addition, in the example shown in FIG. 5, the light detection unit 20c has a configuration in which three photoelectric conversion elements 22a to 22c are provided and detects light in three different wavelength ranges (colors), but the present invention is not limited to this, and a configuration in which two photoelectric conversion elements are provided may be adopted, or a configuration in which four or more photoelectric conversion elements are provided may be adopted. In addition, the light detection unit 20c may have a line sensor or a two-dimensional sensor instead of the plurality of photoelectric conversion elements.

In addition, as will be described in detail later, the reflective diffraction grating 10b can also be configured to diffract incident ambient light in an opposite azimuth direction according to a polarization state thereof. For example, in a case where the reflective diffraction grating 10b is configured to reflect and diffract dextrorotatory circularly polarized light and levorotatory circularly polarized light in azimuth directions different from each other by 180° and the ambient light transmitted through the transmission unit 106 is configured to be unpolarized light incident into the reflective diffraction grating 10b, the dextrorotatory circularly polarized light component and the levorotatory circularly polarized light component of the incident ambient light are diffracted in opposite azimuth directions. In this configuration, the reflection direction of the surface reflection (light that becomes noise) that is not wavelength-separated and the diffraction direction by the diffraction element can be largely changed.

In a case where the dextrorotatory circularly polarized light component and the levorotatory circularly polarized light component of the ambient light incident on the reflective diffraction grating 10b are diffracted in opposite azimuth directions, as in the example shown in FIG. 6, the ambient light sensor system 110e may have a configuration in which two light detection units, that is, the light detection unit 20c that detects each wavelength component of the dextrorotatory circularly polarized light component of the ambient light incident and a light detection unit 20d that detects each wavelength component of the levorotatory circularly polarized light component of the ambient light incident.

In the example shown in FIG. 6, the reflective diffraction grating 10b diffracts one polarized light component in the azimuth direction to the right in the drawing and diffracts the other polarized light component in the azimuth direction to the left in the drawing, and the two light detection units are arranged side by side in the left-right direction. In the example shown in FIG. 6, the photoelectric conversion elements 22a, 22b, and 22c are disposed such that in the ambient light diffracted by the reflective diffraction grating 10b, blue light (two-dot chain line arrow) of the one polarized light component is incident on the photoelectric conversion element 22a of the light detection unit 20c, green light (one-dot chain line arrow) is incident on the photoelectric conversion element 22b, and red light (broken line arrow) is incident on the photoelectric conversion element 22c. In addition, the photoelectric conversion elements 22d, 22e and 22f are disposed such that blue light (two-dot chain line arrow) of the other polarized light component is incident on the photoelectric conversion element 22d of the light detection unit 20d, green light (one-dot chain line arrow) is incident on the photoelectric conversion element 22e, and red light (broken line arrow) is incident on the photoelectric conversion element 22f, in the ambient light diffracted by the reflective diffraction grating 10b.

In this way, in a case where the reflective diffraction grating 10b diffracts the incident ambient light in an opposite azimuth direction according to the polarization state, the amount of light of each wavelength component to be detected can be increased by adopting a configuration in which light in each polarization state is detected. Therefore, the amount of light at each wavelength of the ambient light can be detected with high accuracy.

Here, in the image display apparatus according to the embodiment of the present invention, the ambient light sensor system may further include a light guide plate.

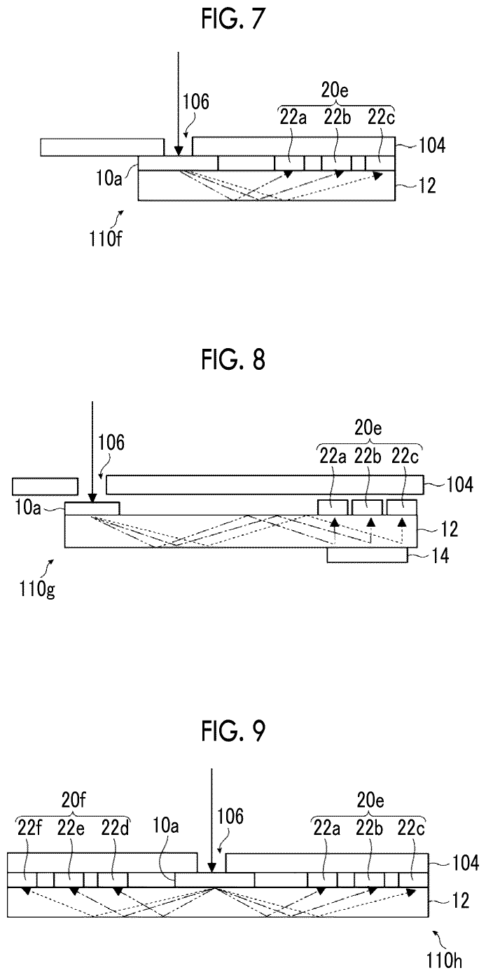

FIG. 7 is a cross-sectional view conceptually showing another example of the image display apparatus according to the embodiment of the present invention.

The image display apparatus shown in FIG. 7 includes an image display panel 104 and an ambient light sensor system 110f.

The ambient light sensor system 110f includes the transmissive diffraction grating 10a, the light guide plate 12, and the light detection unit 20e.

The transmissive diffraction grating 10a is disposed at a position overlapping with the transmission unit 106 in a case of being viewed from a direction perpendicular to the display surface 104a of the image display panel 104. In addition, the light guide plate 12 is disposed in contact with a surface of the transmissive diffraction grating 10a opposite to the transmission unit 106 side.

The light guide plate 12 is a member that guides light inside and has a rectangular parallelepiped shape. The light guide plate 12 is not particularly limited, and a well-known light guide plate of the related art that is used in an image display apparatus or the like can be used.

As shown in FIG. 7, a transmissive diffraction grating 10a is disposed on a surface (main surface) of the light guide plate 12 on one end part side on the image display panel 104 side. In addition, the photoelectric conversion elements 22a to 22c (light detection units 20e) are disposed on the main surface of the light guide plate 12 on the other end part side. In the example shown in the drawing, the transmissive diffraction grating 10a and the photoelectric conversion elements 22a to 22c are disposed on the same main surface of the light guide plate 12, but may be disposed on main surfaces facing each other.

In the ambient light sensor system 110f having such a configuration, the transmissive diffraction grating 10a transmits and diffracts light of each wavelength component at different angles according to the wavelength of the ambient light incident through the transmission unit 106. In the example shown in FIG. 7, the red light (broken line arrow), the green light (one-dot chain line arrow), and the blue light (two-dot chain line arrow) are diffracted at different angles. In addition, in the ambient light sensor system 110f, the transmissive diffraction grating 10a diffracts light of each wavelength component at an angle at which the light is totally reflected in the light guide plate 12. That is, in the ambient light sensor system 110f, the transmissive diffraction grating 10a is an incidence-side diffraction grating for light incidence on the light guide plate 12. The diffracted light is incident on the light guide plate 12, and is guided to the light detection unit 20e side by total reflection in the light guide plate 12. The light of each wavelength component guided in the light guide plate 12 is incident on and detected by the photoelectric conversion elements 22a to 22c of the light detection unit 20e.

In this way, a configuration may be adopted in which the light diffracted by the transmissive diffraction grating 10a is guided by the light guide plate 12 and is detected by the light detection unit 20e (the photoelectric conversion elements 22a to 22c). In such a configuration, since the light detection unit 20e can be disposed at a position farther from the transmission unit 106, the incidence of the noise light on the photoelectric conversion elements 22a to 22c can be more suitably suppressed, and the amount of light of each wavelength of the ambient light can be measured with higher accuracy.

In the example shown in FIG. 7, the light of each wavelength component is shown as being totally reflected once in the light guide plate 12, but the present invention is not limited to this, and a configuration may be adopted in which the light is totally reflected a plurality of times in the light guide plate 12 and guided.

In addition, in the example shown in FIG. 7, the light of each wavelength component guided in the light guide plate 12 is directly incident on the photoelectric conversion elements 22a to 22c disposed on one main surface of the light guide plate 12. However, the present invention is not limited thereto. As in the example shown in FIG. 8, the ambient light sensor system 110g may have a configuration including the emission-side diffraction grating 14 for light emission from the light guide plate 12.

As shown in FIG. 8, in the ambient light sensor system 110g, the emission-side diffraction grating 14 is disposed on a main surface of the light guide plate 12 facing the main surface on which the photoelectric conversion elements 22a to 22c (light detection units 20e) are disposed. The emission-side diffraction grating 14 diffracts the light of each wavelength component guided in the light guide plate 12 such that an angle of the light with respect to a main surface in a traveling direction is an angle outside a total reflection condition. Specifically, the emission-side diffraction grating 14 diffracts the light having each wavelength component such that the light is incident at an angle closer to a direction perpendicular to the photoelectric conversion elements 22a to 22c. Therefore, the light of each wavelength components can be more suitably detected by the photoelectric conversion elements 22a to 22c.

In the example shown in FIG. 8, the photoelectric conversion elements 22a to 22c are disposed in contact with the main surface of the light guide plate 12. However, in a case of a configuration including the emission-side diffraction grating 14, the photoelectric conversion elements 22a to 22c may be disposed to be spaced apart from the light guide plate 12.

In addition, even in the examples of FIGS. 9 to 11 described below, the ambient light sensor system may have a configuration in which an emission-side diffraction grating for light emission from the light guide plate 12 is provided.

As the emission-side diffraction grating 14, the same diffraction grating as the reflective diffraction grating 10b can be used. In addition, as the emission-side diffraction grating, the same diffraction grating as the transmissive diffraction grating 10a can also be used. In this case, as a configuration in which a transmissive diffraction grating is disposed between the light guide plate and the light detection unit, the transmissive diffraction grating may diffract the light guided in the light guide plate toward the light detection unit.

In addition, as described above, in a case where the liquid crystal diffraction element is used as the transmissive diffraction grating 10a, the liquid crystal diffraction element diffracts the incident ambient light in an opposite azimuth direction according to the polarization state thereof. Therefore, even in a case where the ambient light sensor system includes the light guide plate, as shown in FIG. 9, the ambient light sensor system 110h may have a configuration in which two light detection units including a light detection unit 20e that detects respective wavelength components of a dextrorotatory circularly polarized light component of the incident ambient light and a light detection unit 20f that detects respective wavelength components of a levorotatory circularly polarized light component of the incident ambient light.

In the example shown in FIG. 9, the transmissive diffraction grating 10a of the ambient light sensor system 110h diffracts one polarized light component in an azimuth direction toward the right in the drawing and diffracts the other polarized light component in an azimuth direction toward the left in the drawing, and is disposed in a substantially center portion in the light guide direction of the main surface of the light guide plate 12 on the image display panel 104 side. In addition, the light detection unit 20e (photoelectric conversion elements 22a to 22c) is disposed at one end part of the main surface of the light guide plate 12 on the image display panel 104 side, and the light detection unit 20f (photoelectric conversion elements 22d to 22f) is disposed at the other end part.

In the example shown in FIG. 9, the transmissive diffraction grating 10a diffracts light of each wavelength component at an angle at which the light is totally reflected in the light guide plate 12. In this case, the light is diffracted in the opposite azimuth direction depending on the polarization state of the incident ambient light. Accordingly, in the ambient light diffracted by the transmissive diffraction grating 10a, one polarized light component is guided in the right direction in the drawing in the light guide plate 12, blue light (two-dot chain line arrow) of this polarized light component is incident on the photoelectric conversion element 22a of the light detection unit 20e, green light (one-dot chain line arrow) is incident on the photoelectric conversion element 22b, and red light (broken line arrow) is incident on the photoelectric conversion element 22c. In addition, in the ambient light diffracted by the transmissive diffraction grating 10a, the other polarized light component is guided in the light guide plate 12 in the left direction in the drawing, blue light (two-dot chain line arrow) of the polarized light component is incident on the photoelectric conversion element 22d of the light detection unit 20f, green light (one-dot chain line arrow) is incident on the photoelectric conversion element 22e, and red light (broken line arrow) is incident on the photoelectric conversion element 22f.

In this way, in a case where the transmissive diffraction grating 10a diffracts the incidence ambient light in the opposite azimuth direction according to the polarization state, the amount of light of each wavelength component to be detected can be increased by the configuration in which the light in each polarization state is detected. Therefore, the amount of light at each wavelength of the ambient light can be detected with high accuracy. In addition, since the light diffracted by the transmissive diffraction grating 10a is guided to be incident on the light detection unit using the light guide plate 12, the light detection unit can be disposed at a position farther from the transmission unit 106, and the incidence of the noise light on the photoelectric conversion elements 22a to 22f can be more suitably suppressed. Accordingly, the amount of light at each wavelength of the ambient light can be measured with higher accuracy.

In addition, even in a case where the ambient light sensor system includes the reflective diffraction grating 10b as the diffraction grating, the ambient light sensor system may further include a light guide plate.

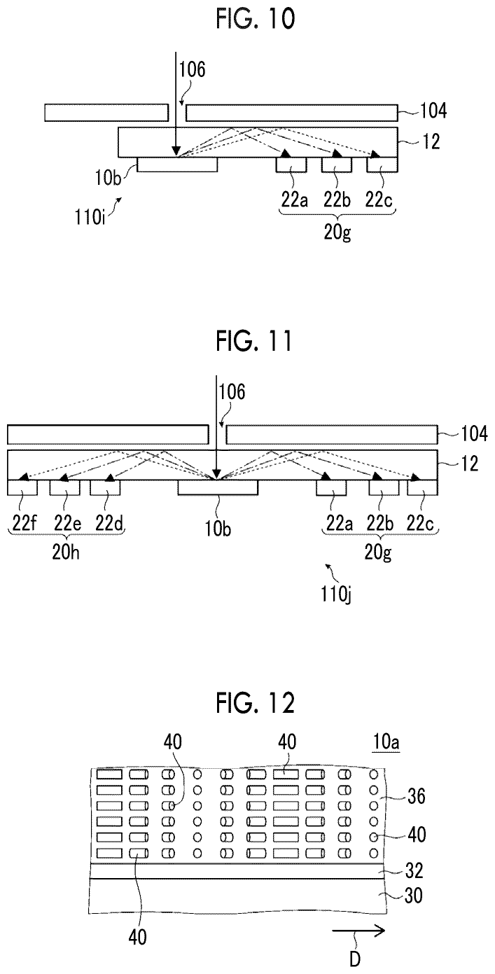

FIG. 10 is a cross-sectional view conceptually showing another example of the image display apparatus according to the embodiment of the present invention.

The image display apparatus shown in FIG. 10 includes an image display panel 104 and an ambient light sensor system 110i.

The ambient light sensor system 110i includes the reflective diffraction grating 10b, the light guide plate 12, and the light detection unit 20e.

The reflective diffraction grating 10b is disposed at a position overlapping with the transmission unit 106 in a case of being viewed from a direction perpendicular to the display surface 104a of the image display panel 104. In addition, the reflective diffraction grating 10b is disposed to be spaced apart from the image display panel 104 in a direction perpendicular to the display surface 104a. In addition, the light guide plate 12 is disposed to be in contact with a surface of the reflective diffraction grating 10b on the transmission unit 106 side. That is, the light guide plate 12 is disposed between the transmission unit 106 and the reflective diffraction grating 10b.

As shown in FIG. 10, a reflective diffraction grating 10b is disposed on a surface (main surface) of the light guide plate 12 on one end part side opposite to the image display panel 104 side. In addition, the photoelectric conversion elements 22a to 22c (light detection units 20g) are disposed on the main surface of the light guide plate 12 on the other end part side. In the example shown in the drawing, the reflective diffraction grating 10b and the photoelectric conversion elements 22a to 22c are disposed on the same main surface of the light guide plate 12, but may be disposed on main surfaces facing each other.

In the ambient light sensor system 110i having such a configuration, the ambient light that passes through the transmission unit 106 and is incident on the main surface of the light guide plate 12 substantially perpendicularly reaches the reflective diffraction grating 10b, and the light of each wavelength component is reflected and diffracted at different angles according to the wavelengths. In the example shown in FIG. 10, the red light (broken line arrow), the green light (one-dot chain line arrow), and the blue light (two-dot chain line arrow) are diffracted at different angles. In addition, in the ambient light sensor system 110i, the reflective diffraction grating 10b diffracts light of each wavelength component at an angle at which the light is totally reflected in the light guide plate 12. That is, in the ambient light sensor system 110i, the reflective diffraction grating 10b is an incidence-side diffraction grating for light incidence on the light guide plate 12. The diffracted light is incident on the light guide plate 12, and is guided to the light detection unit 20g side by total reflection in the light guide plate 12. The light of each wavelength component guided in the light guide plate 12 is incident on and detected by the photoelectric conversion elements 22a to 22c of the light detection unit 20g.

As described above, a configuration may be adopted in which light diffracted by the reflective diffraction grating 10b is guided by the light guide plate 12 and is detected by the light detection unit 20g (the photoelectric conversion elements 22a to 22c). With such a configuration, the light detection unit 20g can be disposed at a position farther from the transmission unit 106, and thus, the incidence of the noise light on the photoelectric conversion elements 22a to 22c can be more suitably suppressed, and the amount of light of each wavelength of the ambient light can be measured with higher accuracy.

In addition, in a case where the reflective diffraction grating 10b diffracts the dextrorotatory circularly polarized light component and the levorotatory circularly polarized light component of the incident ambient light in opposite azimuth directions, as in the example shown in FIG. 11, the ambient light sensor system 110j may have a configuration in which two light detection units, that is, a light detection unit 20g that detects each wavelength component of the dextrorotatory circularly polarized light component of the incident ambient light and a light detection unit 20h that detects each wavelength component of the levorotatory circularly polarized light component are provided.

In the example shown in FIG. 11, the reflective diffraction grating 10b of the ambient light sensor system 110j diffracts one polarized light component in the azimuth direction to the right in the drawing and diffracts the other polarized light component in the azimuth direction to the left in the drawing, and is disposed in a substantially center portion in the light guide direction of the main surface of the light guide plate 12 opposite to the image display panel 104. In addition, a light detection unit 20g (photoelectric conversion elements 22a to 22c) is disposed at one end part of a main surface of the light guide plate 12 opposite to the image display panel 104, and a light detection unit 20h (photoelectric conversion elements 22d to 22f) is disposed at the other end part.

In the example shown in FIG. 11, the reflective diffraction grating 10b diffracts light of each wavelength component at an angle at which the light is totally reflected in the light guide plate 12. In this case, the light is diffracted in the opposite azimuth direction depending on the polarization state of the incident ambient light. Accordingly, in the ambient light diffracted by the reflective diffraction grating 10b, one polarized light component is guided in the right direction in the drawing in the light guide plate 12, blue light (two-dot chain line arrow) of this polarized light component is incident on the photoelectric conversion element 22a of the light detection unit 20g, green light (one-dot chain line arrow) is incident on the photoelectric conversion element 22b, and red light (broken line arrow) is incident on the photoelectric conversion element 22c. In addition, in the ambient light diffracted by the reflective diffraction grating 10b, the other polarized light component is guided in the light guide plate 12 in the left direction in the drawing, blue light (two-dot chain line arrow) of the polarized light component is incident on the photoelectric conversion element 22d of the light detection unit 20h, green light (one-dot chain line arrow) is incident on the photoelectric conversion element 22e, and red light (broken line arrow) is incident on the photoelectric conversion element 22f.

In this way, in a case where the reflective diffraction grating 10b diffracts the incident ambient light in an opposite azimuth direction according to the polarization state, the amount of light of each wavelength component to be detected can be increased by adopting a configuration in which light in each polarization state is detected. Therefore, the amount of light at each wavelength of the ambient light can be detected with high accuracy. In addition, since the light guide plate 12 is used to guide the light diffracted by the reflective diffraction grating 10b to be incident into the light detection unit, the light detection unit can be disposed at a position farther from the transmission unit 106, and the incidence of the noise light into the photoelectric conversion elements 22a to 22f can be more suitably suppressed. Accordingly, the amount of light at each wavelength of the ambient light can be measured with higher accuracy.

The image display apparatus according to the embodiment of the present invention may be configured to include at least one of a lens, a prism, a louver, a phase difference plate, or an anisotropic light absorbing layer, which is disposed at, at least one of the transmission unit 106 of the image display panel 104 or between the transmission unit 106 and the diffraction grating (the transmissive diffraction grating 10a or the reflective diffraction grating 10b).

For example, by disposing a lens (prism) that focuses or collimates the ambient light incident from the transmission unit 106 as the lens or the prism, the amount of light diffracted by the diffraction grating and detected by the light detection unit can be improved.

In addition, the louver and the anisotropic light absorbing layer transmit the ambient light incident on the transmission unit 106 from a direction perpendicular to the display surface 104a of the image display panel 104 and block the reflected light inside the panel incident from an oblique direction. As a result, it is possible to suppress the occurrence of noise due to the incidence of light having a certain wavelength component that is incident from an oblique direction and diffracted by the diffraction element from an oblique direction into the photoelectric conversion element other than the corresponding photoelectric conversion element. In a case where the anisotropic absorption layer is used, the anisotropic absorption layer may be used as a single layer, in combination with a λ/2 plate, in combination with a twist layer, or in a laminate of an anisotropic absorption layer and a λ/2 plate or a twist layer and an anisotropic absorption layer, depending on the internal polarization state.

In addition, for example, in a case where the image display panel 104 includes a linear polarizer and the ambient light transmitted through the transmission unit 106 is converted into linearly polarized light, the N/4 plate is provided as the phase difference plate, so that the linearly polarized light transmitted through the transmission unit 106 can be converted into circularly polarized light, and the efficiency can be further improved in a case where the liquid crystal diffraction element is used as the diffraction grating.

Hereinafter, the diffraction grating will be described.

### [Diffraction Grating]

As described above, as the transmissive diffraction grating and the reflective diffraction grating, a well-known diffraction element that can diffract incident light while transmitting or reflecting the light and can diffract the light at different angles depending on the wavelength, such as a liquid crystal diffraction element, a surface relief type diffraction element, and a metasurface, can be used.

### [Surface Relief Type Diffraction Element]

As the surface relief type diffraction element, a well-known surface relief type diffraction element can be used. The surface relief type diffraction element is configured such that linear fine uneven portions are alternately arranged on the surface in parallel at a predetermined period. The period of the diffraction structure, the material, the height of the convex portion, and the like may be appropriately set depending on the wavelength range to be diffracted.

In addition, the surface relief type diffraction element may be a diffraction element in which a diffraction structure (concave-convex structure) is formed on a surface of a film-like material consisting of a resin or the like, or may be a diffraction element in which a diffraction structure (concave-convex structure) is directly formed on a surface of a light guide plate.

### [Metasurface-Type Diffraction Element]

The metasurface-type diffraction element is a so-called metasurface structure in which a large number of microstructures are arranged on a surface of a base material layer. In the metasurface structure, by appropriately designing the shape and the forming material of the microstructure, the arrangement of the microstructures, the interval (pitch) between the microstructures, and the like, a diffraction grating that diffracts light having a certain wavelength at a desired angle can be obtained. The metasurface structure may be designed by a known method according to the desired optical characteristics. As an example, the arrangement of the microstructures and the like may be set using commercially available simulation software.

### [Transmissive Liquid Crystal Diffraction Element]

The transmissive liquid crystal diffraction element is a liquid crystal diffraction element that has a liquid crystal alignment pattern in which the liquid crystal compound continuously rotates in at least one in-plane direction, and the liquid crystal compound does not form a cholesteric liquid crystalline phase in a thickness direction. The liquid crystal diffraction element may have a configuration in which the liquid crystal compound is twisted and rotates in the thickness direction to some extent that a cholesteric liquid crystalline phase is not formed.

FIG. 12 shows an example of the transmissive liquid crystal diffraction element.

A transmissive liquid crystal diffraction element 10a shown in FIG. 12 includes a support 30, an alignment film 32, and an optically anisotropic layer 36.

The transmissive liquid crystal diffraction element 10a of the example shown in FIG. 12 includes the support 30, the alignment film 32, and the optically anisotropic layer 36, but the present invention is not limited thereto. The transmissive liquid crystal diffraction element may have only the alignment film 32 and the optically anisotropic layer 36 by peeling off the support 30, for example. Alternatively, the transmissive liquid crystal diffraction element may include only the optically anisotropic layer 36 obtained by peeling off the support 30 and the alignment film 32.

### <Support>

The support 30 supports the alignment film 32 and the optically anisotropic layer 36.

As the support 30, various sheet-like materials (films or plate-shaped materials) can be used as long as they can support the alignment film 32 and the optically anisotropic layer 36.

A transmittance of the support 30 with respect to corresponding light is preferably 50% or higher, more preferably 70% or higher, and still more preferably 85% or higher.

The thickness of the support 30 is not particularly limited and may be appropriately set depending on the use of the transmissive liquid crystal diffraction element, a material for forming the support 30, and the like in a range where the alignment film 32 and the optically anisotropic layer 36 can be supported.

The thickness of the support 30 is preferably 1 to 2000 μm, more preferably 3 to 500 μm, and still more preferably 5 to 250 μm.

The support 30 may have a monolayer structure or a multi-layer structure.

In a case where the support 30 has a monolayer structure, examples thereof include supports formed of glass, triacetyl cellulose (TAC), polyethylene terephthalate (PET), polycarbonates, polyvinyl chloride, acryl, polyolefin, and the like. In a case where the support 30 has a multi-layer structure, examples thereof include a support including: one of the above-described supports having a monolayer structure that is provided as a substrate; and another layer that is provided on a surface of the substrate.

### <Alignment Film>

In the transmissive liquid crystal diffraction element, the alignment film 32 is formed on the surface of the support 30.

The alignment film 32 is an alignment film for aligning the liquid crystal compound 40 to the predetermined liquid crystal alignment pattern during the formation of the optically anisotropic layer 36.

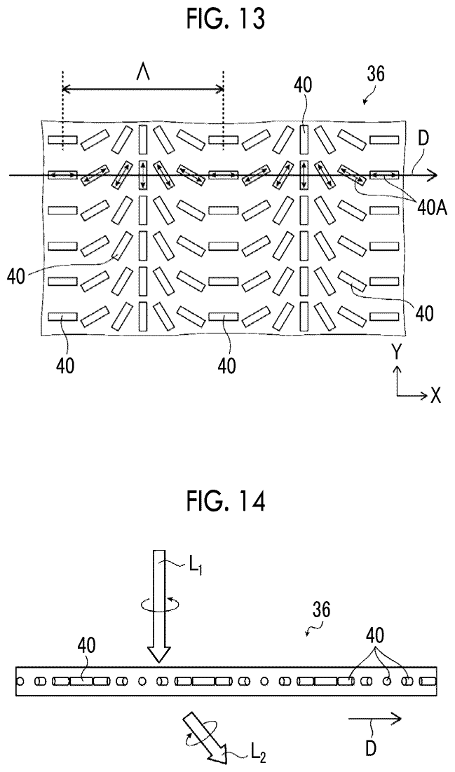

Although described below, in the present invention, the optically anisotropic layer 36 has a liquid crystal alignment pattern in which an orientation of an optical axis 40A (refer to FIG. 13) derived from the liquid crystal compound 40 changes while continuously rotating in at least one in-plane direction. Accordingly, the alignment film 32 is formed such that the optically anisotropic layer 36 can form the liquid crystal alignment pattern.

In the following description, “the orientation of the optical axis 40A rotates” will also be simply referred to as “the optical axis 40A rotates”.

As the alignment film 32, various well-known films can be used.

Examples of the alignment film include a rubbed film formed of an organic compound such as a polymer, an obliquely deposited film formed of an inorganic compound, a film having a microgroove, and a film formed by lamination of Langmuir-Blodgett (LB) films formed with a Langmuir-Blodgett's method using an organic compound such as @-tricosanoic acid, dioctadecylmethylammonium chloride, and methyl stearate.

The alignment film 32 formed by a rubbing treatment can be formed by rubbing a surface of a polymer layer with paper or fabric in a given direction multiple times.

The material to be used in the alignment film 32 is preferably polyimide, polyvinyl alcohol, a polymer having a polymerizable group described in JP1997-152509A (JP-H9-152509A), or a material for forming the alignment film 32 or the like, such a material as described in JP2005-97377A, JP2005-99228A, or JP2005-128503A.

In the transmissive liquid crystal diffraction element, the alignment film 32 can be suitably used as a so-called photo-alignment film obtained by irradiating a photo-alignment material with polarized light or non-polarized light. That is, in the transmissive liquid crystal diffraction element, a photo-alignment film formed by applying a photo-alignment material to the support 30 is suitably used as the alignment film 32.

The irradiation of polarized light can be performed in a direction orthogonal or oblique to the photo-alignment film, and the irradiation of non-polarized light can be performed in an oblique direction with respect to the photo-alignment film.

Preferable examples of the photo-alignment material used in the alignment film that can be used in the present invention include: an azo compound described in JP2006-285197A, JP2007-76839A, JP2007-138138A, JP2007-94071A, JP2007-121721A, JP2007-140465A, JP2007-156439A, JP2007-133184A, JP2009-109831A, JP3883848B, and JP4151746B; an aromatic ester compound described in JP2002-229039A; a maleimide- and/or alkenyl-substituted nadiimide compound having a photo-alignable unit described in JP2002-265541A and JP2002-317013A; a photocrosslinking silane derivative described in JP4205195B and JP4205198B, a photocrosslinking polyimide, a photocrosslinking polyamide, or a photocrosslinking polyester described in JP2003-520878A, JP2004-529220A, and JP4162850B; and a photodimerizable compound, in particular, a cinnamate compound, a chalcone compound, or a coumarin compound described in JP1997-118717A (JP-H9-118717A), JP1998-506420A (JP-H10-506420A), JP2003-505561A, WO2010/150748A, JP2013-177561A, and JP2014-12823A.

Among these, the azo compound, the photocrosslinking polyimide, the photocrosslinking polyamide, the photocrosslinking polyester, the cinnamate compound, or the chalcone compound is suitably used.

The thickness of the alignment film 32 is not particularly limited. The thickness with which a required alignment function can be obtained may be appropriately set depending on the material for forming the alignment film 32.

The thickness of the alignment film 32 is preferably 0.01 to 5 μm and more preferably 0.05 to 2μ m.

A method of forming the alignment film 32 is not limited. Any one of various well-known methods corresponding to a material for forming the alignment film 32 can be used. For example, a method including: applying the alignment film 32 to a surface of the support 30; drying the applied alignment film 32; and exposing the alignment film 32 to laser light to form an alignment pattern can be used.

FIG. 18 conceptually shows an example of an exposure device that exposes the alignment film 32 to form an alignment pattern.

An exposure device 60 shown in FIG. 18 includes a light source 64 including a laser 62, a λ/2 plate 65 that changes a polarization direction of laser light M emitted from the laser 62, a beam splitter 68 that splits the laser light M emitted from the laser 62 into two beams MA and MB, mirrors 70A and 70B that are disposed on optical paths of the split two beams MA and MB, and λ/4 plates 72A and 72B.

Furthermore, the light source 64 emits linearly polarized light P₀. The λ/4 plate 72A converts the linearly polarized light P₀ (beam MA) into dextrorotatory circularly polarized light P_{R}, and the λ/4 plate 72B converts the linearly polarized light P₀ (beam MB) into levorotatory circularly polarized light P_{L}.

The support 30 having the alignment film 32 on which the alignment pattern is not yet formed is disposed at an exposed portion, the two beams MA and MB intersect and interfere with each other on the alignment film 32, and the alignment film 32 is irradiated with and exposed to the interference light.

Due to the interference at this time, the polarization state of light with which the alignment film 32 is irradiated periodically changes according to interference fringes. This makes it possible to obtain an alignment film (hereinafter also referred to as a “patterned alignment film”) having an alignment pattern in which the alignment state changes periodically.

In the exposure device 60, the period of the alignment pattern can be adjusted by changing an intersecting angle α between the two rays MA and MB. That is, by adjusting the intersecting angle α in the exposure device 60, in the alignment pattern in which the optical axis 40A derived from the liquid crystal compound 40 continuously rotates along one direction, the length of the single period over which the optical axis 40A rotates by 180° in the one direction in which the optical axis 40A rotates can be adjusted.

By forming the optically anisotropic layer 36 on the alignment film 32 having the alignment pattern in which the alignment state periodically changes, as described below, the optically anisotropic layer 36 having the liquid crystal alignment pattern in which the optical axis 40A derived from the liquid crystal compound 40 continuously rotates in the one direction can be formed.

In addition, by rotating each of the optical axes of the λ/4 plates 72A and 72B by 90°, the rotation direction of the optical axis 40A can be reversed.

As described above, the patterned alignment film has an alignment pattern to obtain the liquid crystal alignment pattern in which the liquid crystal compound is aligned such that the orientation of the optical axis of the liquid crystal compound in the optically anisotropic layer 36 formed on the patterned alignment film changes while continuously rotating in at least one in-plane direction. In a case where an axis along the orientation in which the liquid crystal compound is aligned is an alignment axis, it can be said that the patterned alignment film has an alignment pattern in which the orientation of the alignment axis changes while continuously rotating in at least one in-plane direction. The alignment axis of the patterned alignment film can be detected by measuring absorption anisotropy. For example, in a case where the patterned alignment film is irradiated with linearly polarized light while rotating the patterned alignment film and the amount of light transmitted through the patterned alignment film is measured, the orientation with which the amount of light is maximum or minimum is observed by gradually changing along at least one in-plane direction.

In the present invention, the alignment film 32 is provided as a preferable aspect and is not a configuration requirement.

For example, the following configuration can also be adopted, in which, by forming the alignment pattern on the support 30 using a method of rubbing the support 30, a method of processing the support 30 with laser light or the like, the optically anisotropic layer 36 has the liquid crystal alignment pattern in which the orientation of the optical axis 40A derived from the liquid crystal compound 40 changes while continuously rotating in at least one in-plane direction. That is, in the present invention, the support 30 may be made to act as the alignment film.

### <Optically Anisotropic Layer>

In the transmissive liquid crystal diffraction element, the optically anisotropic layer 36 is formed on a surface of the alignment film 32.

The optically anisotropic layer 36 is an optically anisotropic layer obtained by aligning and immobilizing a liquid crystal compound in a liquid crystal alignment pattern in which an orientation of an optical axis derived from the liquid crystal compound changes while continuously rotating in at least one in-plane direction.

As shown in FIG. 13, the optically anisotropic layer 36 has a liquid crystal alignment pattern in which the optical axis 40A of the liquid crystal compound 40 continuously rotates in the arrangement axis D direction. Furthermore, FIG. 13 shows only the liquid crystal compound on the surface of the alignment film 32.

In the transmissive liquid crystal diffraction element 10a, the liquid crystal compound 40 forming the optically anisotropic layer 36 is not helically twisted and does not rotate in the thickness direction, and the optical axis 40A is positioned at the same position in the plane direction.

As described above, the optically anisotropic layer 36 has the liquid crystal alignment pattern in which the orientation of the optical axis 40A derived from the liquid crystal compound 40 changes while continuously rotating along the arrangement axis D direction in the plane.

Meanwhile, regarding the liquid crystal compound 40 forming the optically anisotropic layer 36, the liquid crystal compounds 40 in which the orientations of the optical axes 40A are the same as one another are arranged at equal intervals in the Y direction orthogonal to the arrangement axis D direction, that is, the Y direction orthogonal to one direction in which the optical axes 40A continuously rotate.

In other words, regarding the liquid crystal compound 40 forming the optically anisotropic layer 36, in the liquid crystal compounds 40 arranged in the Y direction, angles between the orientations of the optical axes 40A and the arrangement axis D direction are the same.

Furthermore, “the orientation of the optical axis 40A of the liquid crystal compound 40 changes while continuously rotating in the one in-plane direction along the arrangement axis D” means that angles formed between the optical axes 40A of the liquid crystal compounds 40 and the arrangement axes D vary depending on positions in the arrangement axis D direction, and the angles formed between the optical axes 40A and the arrangement axes D gradually change from θ to θ+180° or θ−180° along the arrangement axis D. That is, in each of the plurality of liquid crystal compounds 40 arranged along the arrangement axis D, as shown in FIG. 13, the optical axis 40A changes along the arrangement axis D while rotating on a certain angle basis.

Furthermore, a difference between the angles of the optical axes 40A of the liquid crystal compounds 40 adjacent to each other in the arrangement axis D direction is preferably 45° or less, more preferably 15° or less, and still more preferably the less angles.

In addition, in the present specification, in a case where the liquid crystal compound 40 is a rod-like liquid crystal compound, the optical axis 40A of the liquid crystal compound 40 refers to a molecular major axis of the rod-like liquid crystal compound. On the other hand, in a case where the liquid crystal compound 40 is a disk-like liquid crystal compound, the optical axis 40A of the liquid crystal compound 40 refers to an axis parallel to the normal direction with respect to a disc plane of the disk-like liquid crystal compound.

In the optically anisotropic layer 36, in the liquid crystal alignment pattern of the liquid crystal compound 40, the length (distance) over which the optical axis 40A of the liquid crystal compound 40 rotates by 180° in the arrangement axis D direction in which the optical axis 40A changes while continuously rotating in a plane is the length Λ of the single period in the liquid crystal alignment pattern.

That is, a distance between centers of two liquid crystal compounds 40 in the arrangement axis D direction is the length Λ of the single period, the two liquid crystal compounds 40 having the same angle in the arrangement axis D direction. Specifically, as shown in FIG. 13, a distance between centers in the arrangement axis D direction of two liquid crystal compounds 40 in which the arrangement axis D direction and the direction of the optical axis 40A match each other is the length Λ of the single period. In the following description, the length Λ of the single period will also be referred to as a “single period Λ”.

In the liquid crystal alignment pattern of the optically anisotropic layer 36, the single period Λ is repeated in the arrangement axis D direction, that is, in the one direction in which the orientation of the optical axis 40A changes while continuously rotating.

On the other hand, in the liquid crystal compounds arranged in the Y direction in the optically anisotropic layer 36, the angles formed between the optical axes 40A and the arrangement axis D direction (the one direction in which the orientation of the optical axis of the liquid crystal compound 40 rotates) are the same. A region in which the liquid crystal compounds 40 in which the angles formed between the optical axes 40A and the arrangement axis D direction are the same are arranged in the Y direction will be referred to as a region R.

In this case, it is preferable that the value of the in-plane retardation (Re) in each region R is a half wavelength, that is, λ/2. The in-plane retardation is calculated from the product of a difference Δn in refractive index generated by refractivity anisotropy of the region R and the thickness of the optically anisotropic layer. Here, the difference in refractive index generated by refractivity anisotropy of the region R in the optically anisotropic layer is defined by a difference between a refractive index of a direction of an in-plane slow axis of the region R and a refractive index of a direction orthogonal to the direction of the slow axis. That is, the difference in refractive index Δn due to the refractivity anisotropy of the regions R is the same as a difference between a refractive index of the liquid crystal compound 40 in the direction of the optical axis 40A and a refractive index of the liquid crystal compound 40 in the direction perpendicular to the optical axis 40A in the plane of the region R. That is, the difference Δn in refractive index is the same as the difference in refractive index of the liquid crystal compound 40.

In a case where circularly polarized light is incident into the above-described optically anisotropic layer 36, the light is refracted such that the direction of the circularly polarized light is converted.

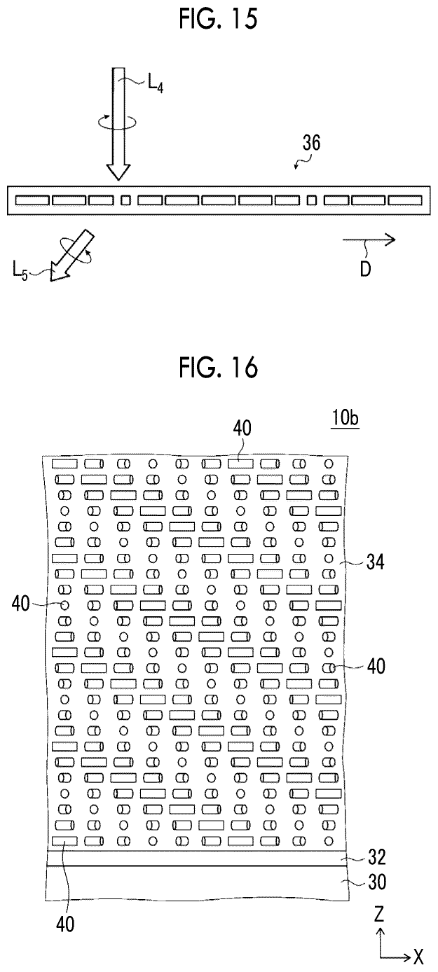

This action is conceptually shown in FIGS. 14 and 15. In the optically anisotropic layer 36, the value of the product of the difference in refractive index of the liquid crystal compound and the thickness of the optically anisotropic layer is λ/2.

As shown in FIG. 14, in a case where a value of the product of the difference in refractive index of the liquid crystal compound of the optically anisotropic layer 36 and the thickness of the optically anisotropic layer 36 is λ/2 and incidence rays L₁ that is levorotatory circularly polarized light is incident on the optically anisotropic layer, the incidence rays L₁ pass through the optically anisotropic layer 36, thereby imparting a phase difference of 180°, and are converted into levorotatory circularly polarized transmission rays L₂.

In addition, the liquid crystal alignment pattern formed in the optically anisotropic layer 36 is a pattern which is periodic in the arrangement axis D direction, so that the transmitted ray L₂ travels in a direction different from a traveling direction of the incidence ray L₁. In this way, the levorotatory circularly polarized incidence rays L₁ are converted into dextrorotatory circularly polarized transmission rays L₂, which are tilted by a predetermined angle in the arrangement axis D direction with respect to an incidence direction.

On the other hand, in a case where the value of the product of a difference in refractive index of the liquid crystal compound of the optically anisotropic layer 36 and a thickness of the optically anisotropic layer 36 is λ/2, as shown in FIG. 15, as incidence rays L₄ of dextrorotatory circularly polarized light is incident on the optically anisotropic layer, the incidence rays L₄ pass through the optically anisotropic layer 36, thereby imparting a phase difference of 180°, and are converted into levorotatory circularly polarized transmission rays L₅.

In addition, the liquid crystal alignment pattern formed in the optically anisotropic layer 36 is a pattern which is periodic in the arrangement axis D direction, so that the transmitted ray L₅ travels in a direction different from a traveling direction of the incidence ray L₄. In this case, the transmitted Light L₅ travels in a direction different from the transmitted light L₂, that is, in a direction opposite to the arrangement axis D direction with respect to the incidence direction. In this way, the incidence rays L₄ are converted into levorotatory circularly polarized transmission rays L₅, which are tilted by a predetermined angle in a direction opposite to the arrangement axis D direction with respect to the incidence direction.

The optically anisotropic layer 36 can adjust refraction angles of the transmitted rays L₂ and L₅ by changing one period Λ of the formed liquid crystal alignment pattern. Specifically, even in the optically anisotropic layer 36, as the single period Λ of the liquid crystal alignment pattern decreases, light components transmitted through the liquid crystal compounds 40 adjacent to each other more strongly interfere with each other. Therefore, the transmitted light components L₂ and L₅ can be more largely refracted.

In addition, by reversing the rotation direction of the optical axis 40A of the liquid crystal compound 40 that rotates in the arrangement axis D direction, the refraction direction of transmitted light can be reversed. That is, in the example FIGS. 14 and 15, the rotation direction of the optical axis 40A toward the arrangement axis D direction is clockwise. By setting this rotation direction to be counterclockwise, the refraction direction of transmitted light can be reversed.

From the viewpoint of diffraction efficiency, in a case where the liquid crystal diffraction element that allows transmission of incidence ray and diffracts incidence ray is used, it is preferable to use a liquid crystal diffraction element having a region where the liquid crystal compound is twisted and rotates (the twisted angle is less than 360°). In particular, in a case where light is diffracted at an angle where total reflection occurs in the light guide plate, from the viewpoint of diffraction efficiency, a liquid crystal diffraction element including a region in which a liquid crystal compound is twisted and rotates can be suitably used. In addition, from the viewpoint of diffraction efficiency, it is preferable to use a laminate in which liquid crystal diffraction elements having different angles at which the liquid crystal compound is twisted and rotates is laminated, or it is preferable to use a laminate in which liquid crystal diffraction elements having different directions in which the liquid crystal compound is twisted and rotates are laminated.

### [Reflective Liquid Crystal Diffraction Element]

An example of the reflective liquid crystal diffraction element will be described with reference to FIG. 16.

FIG. 16 is a diagram schematically showing an example of the reflective liquid crystal diffraction element. In addition, the plan view of the reflective liquid crystal diffraction element shown in FIG. 16 has the same configuration as the configuration shown in FIG. 13.

The reflective liquid crystal diffraction element shown in FIG. 16 includes a cholesteric liquid crystal layer 34 that is obtained by immobilizing a cholesteric liquid crystalline phase and has a liquid crystal alignment pattern in which an orientation of an optical axis derived from a liquid crystal compound changes while continuously rotating in at least one in-plane direction. The cholesteric liquid crystal layer reflects one circularly polarized light having a selective reflection wavelength, and allows transmission of light in other wavelength ranges and other circularly polarized light. Accordingly, the diffraction element including the cholesteric liquid crystal layer is a reflective diffraction element.

In the example shown in FIG. 16, the reflective liquid crystal diffraction element includes the support 30, the alignment film 32, and the cholesteric liquid crystal layer 34.

In the example shown in FIG. 16, the reflective liquid crystal diffraction element includes the support 30, the alignment film 32, and the cholesteric liquid crystal layer 34. However, the present invention is not limited to this configuration. The reflective liquid crystal diffraction element may include only the alignment film 32 and the cholesteric liquid crystal layer 34 by peeling off the support 30. Alternatively, the reflective liquid crystal diffraction element may include only the cholesteric liquid crystal layer 34 by peeling off the support 30 and the alignment film 32.

### <Cholesteric Liquid Crystal Layer>

In the reflective liquid crystal diffraction element, the cholesteric liquid crystal layer 34 is formed on a surface of the alignment film 32.

As described above, the cholesteric liquid crystalline phase is a cholesteric liquid crystal layer that is obtained by immobilizing a cholesteric liquid crystalline phase and has a liquid crystal alignment pattern in which a direction of an optical axis derived from a liquid crystal compound changes while continuously rotating in at least one in-plane direction. In the cholesteric liquid crystal layer having the liquid crystal alignment pattern in which the direction of the optical axis derived from the liquid crystal compound changes while continuously rotating in at least one in-plane direction, an arrangement direction of bright portions and dark portions derived from the cholesteric liquid crystalline phase observed with a SEM in a cross-section perpendicular to the main surface of the cholesteric liquid crystal layer is tilted with respect to the main surface of the cholesteric liquid crystal layer.

As conceptually shown in FIG. 16, the cholesteric liquid crystal layer 34 has a helical structure in which the liquid crystal compound 40 is helically turned and laminated as in a cholesteric liquid crystal layer obtained by immobilizing a typical cholesteric liquid crystalline phase. In the helical structure, a configuration in which the liquid crystal compound 40 is helically rotated once (rotated by 360) and laminated is set as one helical pitch, and plural pitches of the helically turned liquid crystal compounds 40 are laminated.

As is well-known, the cholesteric liquid crystal layer obtained by immobilizing a cholesteric liquid crystalline phase has wavelength-selective reflectivity.

Although described below in detail, the selective reflection wavelength range of the cholesteric liquid crystal layer depends on the length of one helical pitch described above in the thickness direction.

Accordingly, in the configuration where wavelength selectivity is imparted to the reflective liquid crystal diffraction element to diffract light having a wavelength that varies depending on each of the reflective liquid crystal diffraction elements, the selective reflection wavelength range of the cholesteric liquid crystal layer may be appropriately set by adjusting the helical pitch P of the cholesteric liquid crystal layer according to each of the reflective liquid crystal diffraction elements.

As shown in FIG. 13, in the X-Y plane of the cholesteric liquid crystal layer 34, the liquid crystal compounds 40 are arranged along a plurality of arrangement axes D parallel to the X-Y plane. On each of the arrangement axes D, the orientation of the optical axis 40A of the liquid crystal compound 40 changes while continuously rotating in the one in-plane direction along the arrangement axis D. Here, for the convenience of description, it is assumed that the arrangement axis D is directed to the X direction. In addition, in the Y direction, the liquid crystal compounds 40 in which the orientations of the optical axes 40A are the same are aligned at equal intervals.

Furthermore, a difference between the angles of the optical axes 40A of the liquid crystal compounds 40 adjacent to each other in the arrangement axis D direction is preferably 45° or less, more preferably 15° or less, and still more preferably the less angles.

In the cholesteric liquid crystal layer 34, in the liquid crystal alignment pattern of the liquid crystal compound 40, the length (distance) over which the optical axis 40A of the liquid crystal compound 40 rotates by 180° in the arrangement axis D direction in which the optical axis 40A changes while continuously rotating in a plane is the length Λ of the single period in the liquid crystal alignment pattern.

That is, a distance between centers of two liquid crystal compounds 40 in the arrangement axis D direction is the length Λ of the single period, the two liquid crystal compounds 40 having the same angle in the arrangement axis D direction. Specifically, as shown in FIG. 13, a distance between centers in the arrangement axis D direction of two liquid crystal compounds 40 in which the arrangement axis D direction and the direction of the optical axis 40A match each other is the length Λ of the single period. In the following description, the length Λ of the single period will also be referred to as a “single period Λ”.

In the liquid crystal alignment pattern of the cholesteric liquid crystal layer 34, the single period Λ is repeated in the arrangement axis D direction, that is, in the one in-plane direction in which the orientation of the optical axis 40A changes while continuously rotating.

On the other hand, in the liquid crystal compound 40 forming the cholesteric liquid crystal layer 34, the orientations of the optical axes 40A are the same in the direction (in FIG. 13, the Y direction) orthogonal to the arrangement axis D direction, that is, the Y direction orthogonal to one direction in which the optical axis 40A continuously rotates.

In other words, in the liquid crystal compound 40 forming the cholesteric liquid crystal layer 34, angles between the optical axes 40A of the liquid crystal compound 40 and the arrangement axis D direction are the same in the Y direction.

In a case where the X-Z plane of the cholesteric liquid crystal layer 34 shown in FIG. 16 is observed with a scanning electron microscope (SEM), a stripe pattern where an arrangement direction is tilted at a predetermined angle with respect to the main surface (X-Y plane) is observed, the arrangement direction being a direction in which bright portions and dark portions resulting from the alignment of the liquid crystal compound are alternately arranged. In this SEM cross section, an interval between the bright portions adjacent to each other or between the dark portions adjacent to each other in a normal direction of lines formed by the bright portions or the dark portions corresponds to a ½ pitch.

Hereinafter, an action of diffraction of the cholesteric liquid crystal layer will be described.

In a cholesteric liquid crystal layer of the related art, a helical axis derived from a cholesteric liquid crystalline phase is perpendicular to the main surface (X-Y plane), and a reflecting surface thereof is parallel to the main surface (X-Y plane). The cholesteric liquid crystalline phase has specular reflectivity. Therefore, for example, in a case where light is incident from the normal direction into the cholesteric liquid crystal layer in the related art, the light is reflected in the normal direction.

On the other hand, the cholesteric liquid crystal layer 34 having the liquid crystal alignment pattern reflects incident light in a state where it is tilted in the arrangement axis D direction.

For example, assuming that the cholesteric liquid crystal layer 34 selectively reflects dextrorotatory circularly polarized light of red light, in a case where light is incident into the cholesteric liquid crystal layer 34, the cholesteric liquid crystal layer 34 reflects only dextrorotatory circularly polarized light of red light and allows transmission of the other light.

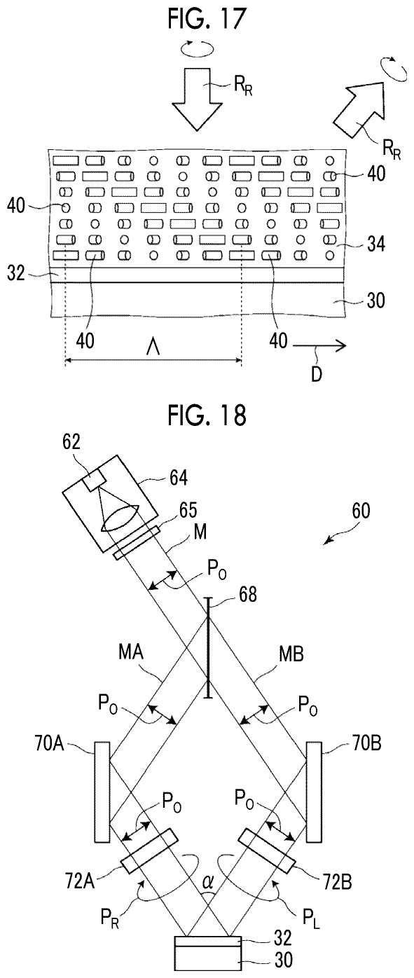

Here, in the cholesteric liquid crystal layer 34, the optical axis 40A of the liquid crystal compound 40 changes while rotating in the arrangement axis D direction (the one in-plane direction). In addition, the liquid crystal alignment pattern formed in the cholesteric liquid crystal layer 34 is a pattern that is periodic in the arrangement axis D direction. Therefore, as shown in FIG. 17, dextrorotatory circularly polarized light RR of red light vertically incident into the cholesteric liquid crystal layer 34 is reflected (diffracted) in a direction (orientation) corresponding to the period of the liquid crystal alignment pattern, and the reflected dextrorotatory circularly polarized light RR of red light is reflected (diffracted) in a direction tilted with respect to the X-Y plane (the main surface of the cholesteric liquid crystal layer) in the arrangement axis D direction (orientation).

Accordingly, in the cholesteric liquid crystal layer 34, by appropriately setting the arrangement axis D as the one direction in which the optical axis 40A rotates, the reflection direction (reflection orientation) of light can be adjusted.

In addition, in a case where circularly polarized light having the same wavelength and the same turning direction is reflected, by reversing the rotation direction of the optical axis 40A of the liquid crystal compound 40 toward the arrangement axis D direction, an azimuth direction of reflection of the circularly polarized light can be reversed.

That is, in FIGS. 14 and 15, the rotation direction of the optical axis 40A toward the arrangement axis D direction is clockwise, and one circularly polarized light is reflected in a state where it is tilted in the arrangement axis D direction. By setting the rotation direction of the optical axis 40A to be counterclockwise, the circularly polarized light is reflected in a state where it is tilted in a direction opposite to the arrangement axis D direction.

Further, in the cholesteric liquid crystal layer having the same liquid crystal alignment pattern, the reflection direction is reversed by adjusting the helical turning direction of the liquid crystal compound 40, that is, the turning direction of circularly polarized light to be reflected.

For example, in a case where the helical turning direction is right-twisted, the liquid crystal layer selectively reflects dextrorotatory circularly polarized light, and has the liquid crystal alignment pattern in which the optical axis 40A rotates clockwise in the arrangement axis D direction. As a result, the dextrorotatory circularly polarized light is reflected in a state where it is tilted in the arrangement axis D direction.

In addition, for example, in a case where the helical turning direction is left-twisted, the liquid crystal layer selectively reflects levorotatory circularly polarized light, and has the liquid crystal alignment pattern in which the optical axis 40A rotates clockwise in the arrangement axis D direction. As a result, the levorotatory circularly polarized light is reflected in a state where it is tilted in a direction opposite to the arrangement axis D direction.

In the cholesteric liquid crystal layer 34 having the liquid crystal alignment pattern, as the single period Λ decreases, the angle of reflected light with respect to the incidence ray increases. That is, as the single period Λ decreases, reflected light is reflected to be largely tilted with respect to incidence ray.

The diffraction angle by the cholesteric liquid crystal layer 34 having the liquid crystal alignment pattern varies depending on the wavelength of light. Specifically, as the wavelength of light increases, the angle of reflected light with respect to incidence ray increases. Accordingly, the cholesteric liquid crystal layer 34 can disperse incident light by diffracting (reflecting) the light at an angle that varies depending on the wavelength.

In addition, as described above, the cholesteric liquid crystal layer according to the embodiment of the present invention reflects and diffracts incident ambient light at an angle that varies depending on each of the wavelengths. That is, the cholesteric liquid crystal layer needs to reflect ambient light having a broad bandwidth. On the other hand, a general cholesteric liquid crystal layer has wavelength-selective reflectivity, and reflects light in a narrow band.

Accordingly, in order to widen the reflection wavelength range, it is preferable that the cholesteric liquid crystal layer according to the embodiment of the present invention has a structure in which the helical pitch changes in the thickness direction. Since the cholesteric liquid crystal layer has the structure in which the helical pitch changes in the thickness direction, the reflection wavelength range of the cholesteric liquid crystal layer can be widened. In addition, in order to widen the reflection wavelength range, it is also preferable to increase a birefringence index (Δn) of liquid crystal.

In the cholesteric liquid crystal layer where the helical pitch changes in the thickness direction, in a stripe pattern of bright portions and dark portions in a cross section observed with a scanning electron microscope (SEM), intervals of the bright portions and the dark portions vary in the thickness direction.

Alternatively, the reflective liquid crystal diffraction element according to the embodiment of the present invention may be configured to include a plurality of cholesteric liquid crystal layers having different helical pitches. In this case, each of the plurality of cholesteric liquid crystal layers has the liquid crystal alignment pattern, and reflects and diffracts light having a selective reflection wavelength in incident ambient light. In addition, by making the diffraction angles by the cholesteric liquid crystal layers different from each other, the cholesteric liquid crystal layers reflect light at different angles (directions).

For example, in a case where the reflective diffraction element (reflective diffraction grating 10b) is configured to reflect incident ambient light at different angles for each of three wavelength ranges of RGB as in the examples shown in FIGS. 5 and 10, the reflective diffraction element may be configured to include a cholesteric liquid crystal layer that reflects red light, a cholesteric liquid crystal layer that reflects green light, and a cholesteric liquid crystal layer that reflects blue light.

In addition, as in the example shown in FIGS. 6 and 11, in a case where the reflective diffraction element (reflective diffraction grating 10b) is configured to reflect the incident ambient light in opposite azimuth directions at different angles for each of three wavelength ranges of RGB according to the polarization state, the reflective diffraction element may be configured to include a cholesteric liquid crystal layer that reflects red light of dextrorotatory circularly polarized light, a cholesteric liquid crystal layer that reflects red light of levorotatory circularly polarized light, a cholesteric liquid crystal layer that reflects green light of dextrorotatory circularly polarized light, a cholesteric liquid crystal layer that reflects green light of levorotatory circularly polarized light, a cholesteric liquid crystal layer that reflects blue light of dextrorotatory circularly polarized light, and a cholesteric liquid crystal layer that reflects blue light of levorotatory circularly polarized light.

In addition, in a case where the reflective diffraction element (reflective diffraction grating 10b) has a configuration in which the incident ambient light is reflected at different angles for each of three wavelength ranges of RGB as in the example shown in FIGS. 5 and 10, and the ambient light incident on the reflective diffraction element is unpolarized light, the reflective diffraction element may have a cholesteric liquid crystal layer that reflects red light of dextrorotatory circularly polarized light, a cholesteric liquid crystal layer that reflects red light of levorotatory circularly polarized light, a cholesteric liquid crystal layer that reflects green light of dextrorotatory circularly polarized light, a cholesteric liquid crystal layer that reflects green light of levorotatory circularly polarized light, a cholesteric liquid crystal layer that reflects blue light of dextrorotatory circularly polarized light, and a cholesteric liquid crystal layer that reflects blue light of levorotatory circularly polarized light, and the cholesteric liquid crystal layers that reflect dextrorotatory circularly polarized light and the cholesteric liquid crystal layers that reflect levorotatory circularly polarized light of the respective colors may be configured to reflect and diffract light in the same azimuth direction. That is, the rotation directions of the optical axes of the liquid crystal compounds in the direction of the arrangement axis D of the liquid crystal alignment pattern may be opposite to each other in the cholesteric liquid crystal layer that reflects dextrorotatory circularly polarized light of each color and the cholesteric liquid crystal layer that reflects levorotatory circularly polarized light. As a result, red light can be reflected and diffracted in the same azimuth direction and at the same angle in the cholesteric liquid crystal layer that reflects dextrorotatory circularly polarized red light and the cholesteric liquid crystal layer that reflects levorotatory circularly polarized red light, green light can be reflected and diffracted in the same azimuth direction and at the same angle in the cholesteric liquid crystal layer that reflects dextrorotatory circularly polarized green light and the cholesteric liquid crystal layer that reflects levorotatory circularly polarized green light, and blue light can be reflected and diffracted in the same azimuth direction and at the same angle in the cholesteric liquid crystal layer that reflects dextrorotatory circularly polarized blue light and the cholesteric liquid crystal layer that reflects levorotatory circularly polarized blue light.

### <<Method of Forming Cholesteric Liquid Crystal Layer (Optically Anisotropic Layer)>>

The above-described optically anisotropic layer and cholesteric liquid crystal layer can be formed by immobilizing a liquid crystal phase in which a liquid crystal compound is aligned in a predetermined state. The optically anisotropic layer can be formed in the same manner as the cholesteric liquid crystal layer except that the liquid crystal composition for forming the optically anisotropic layer does not contain a chiral agent and the liquid crystal compound is not cholesterically aligned. Therefore, in the following description, a method of forming the cholesteric liquid crystal layer will be described as a representative example.

The cholesteric liquid crystal layer can be formed by immobilizing a cholesteric liquid crystalline phase in a layer shape.

The structure in which a cholesteric liquid crystalline phase is immobilized may be a structure in which the alignment of the liquid crystal compound as a cholesteric liquid crystalline phase is immobilized. Typically, the structure in which a cholesteric liquid crystalline phase is immobilized is preferably a structure which is obtained by making the polymerizable liquid crystal compound to be in a state where a cholesteric liquid crystalline phase is aligned, polymerizing and curing the polymerizable liquid crystal compound with ultraviolet irradiation, heating, or the like to form a layer having no fluidity, and concurrently changing the state of the polymerizable liquid crystal compound into a state where the alignment state is not changed by an external field or an external force.

The structure in which a cholesteric liquid crystalline phase is immobilized is not particularly limited as long as the optical characteristics of the cholesteric liquid crystalline phase are maintained, and the liquid crystal compound 40 in the cholesteric liquid crystal layer does not necessarily exhibit liquid crystallinity. For example, the polymerizable liquid crystal compound may be made to have a high molecular weight by a hardening reaction and therefore the liquid crystallinity may be lost.

Examples of a material used for forming the cholesteric liquid crystal layer obtained by immobilizing the cholesteric liquid crystalline phase include a liquid crystal composition containing a liquid crystal compound. It is preferable that the liquid crystal compound is a polymerizable liquid crystal compound.

In addition, the liquid crystal composition used for forming the cholesteric liquid crystal layer may further contain a surfactant and a chiral agent.

### ——Polymerizable Liquid Crystal Compound——

The polymerizable liquid crystal compound may be a rod-like liquid crystal compound or a disk-like liquid crystal compound.

Examples of the rod-like polymerizable liquid crystal compound for forming the cholesteric liquid crystalline phase include a rod-like nematic liquid crystal compound. As the rod-like nematic liquid crystal compounds, azomethine compounds, an azoxy compounds, cyanobiphenyl compounds, cyanophenyl ester compounds, benzoate ester compounds, phenyl cyclohexanecarboxylate ester compounds, cyanophenylcyclohexane compounds, cyano-substituted phenylpyrimidine compounds, alkoxy-substituted phenylpyrimidine compounds, phenyldioxane compounds, tolan compounds, or alkenylcyclohexylbenzonitrile compounds are preferably used. Not only a low-molecular-weight liquid crystal compound but also a polymer liquid crystal compound can be used.

The polymerizable liquid crystal compound can be obtained by introducing a polymerizable group into the liquid crystal compound. Examples of the polymerizable group include an unsaturated polymerizable group, an epoxy group, and an aziridinyl group, and among these, the unsaturated polymerizable group is preferable, and the ethylenically unsaturated polymerizable group is more preferable. The polymerizable group can be introduced into a molecule of the liquid crystal compound by various methods. The number of polymerizable groups in the polymerizable liquid crystal compound is preferably 1 to 6 and more preferably 1 to 3.

Examples of the polymerizable liquid crystal compound include compounds described in Makromol. Chem., (1989), Vol. 190, p. 2255, Advanced Materials (1993), Vol. 5, p. 107, U.S. Pat. Nos. 4,683,327A, 5,622,648A, 5,770,107A, WO95/22586A, WO95/24455A, WO97/00600A, WO98/23580A, WO98/52905A, JP1989-272551A (JP-H1-272551A), JP1994-016616A (JP-H6-016616A), JP1995-110469A (JP-H7-110469A), JP1999-080081A (JP-H11-080081A), and JP2001-328973A. Two or more polymerizable liquid crystal compounds may be used in combination. In a case where two or more polymerizable liquid crystal compounds are used in combination, the alignment temperature can be lowered.

In addition, as a polymerizable liquid crystal compound other than the above-described examples, for example, such a cyclic organopolysiloxane compound having a cholesteric phase as described in JP1982-165480A (JP-S57-165480A) can be used. Further, as the above-described polymer liquid crystal compound, for example, a polymer in which a liquid crystal mesogenic group is introduced into the main chain, a side chain, or both the main chain and a side chain, a polymer cholesteric liquid crystal in which a cholesteryl group is introduced into a side chain, such a liquid crystal polymer as described in JP1997-133810A (JP-H9-133810A), and such a liquid crystal polymer as described in JP1999-293252A (JP-H11-293252A) can be used.

### ——Disk-Like Liquid Crystal Compound——

As the disk-like liquid crystal compound, for example, the compounds described in JP2007-108732A or JP2010-244038A can be preferably used.

In addition, the addition amount of the polymerizable liquid crystal compound in the liquid crystal composition is preferably 75% to 99.9% by mass, more preferably 80% to 99% by mass, and still more preferably 85% to 90% by mass with respect to the solid content mass (mass excluding a solvent) of the liquid crystal composition.

### ——Surfactant——

The liquid crystal composition used for forming the cholesteric liquid crystal layer may include a surfactant.

It is preferable that the surfactant is a compound that can function as an alignment control agent contributing to the stable or rapid alignment of a cholesteric liquid crystalline phase. Examples of the surfactant include a silicone-based surfactant and a fluorine-based surfactant, and preferred examples thereof include the fluorine-based surfactant.

Specific examples of the surfactant include compounds described in paragraphs “0082” to “0090” of JP2014-119605A, compounds described in paragraphs “0031” to “0034” of JP2012-203237A, exemplary compounds described in paragraphs “0092” and “0093” of JP2005-099248A, exemplary compounds described in paragraphs “0076” to “0078” and “0082” to “0085” of JP2002-129162A, and fluorine (meth)acrylate polymers described in paragraphs “0018” to “0043” of JP2007-272185A.

The surfactants may be used alone or in combination of two or more kinds.

As the fluorine-based surfactant, the compounds described in paragraphs “0082” to “0090” of JP2014-119605A are preferable.

The addition amount of the surfactant in the liquid crystal composition is preferably 0.01% to 10% by mass, more preferably 0.01% to 5% by mass, and still more preferably 0.02% to 1% by mass with respect to the total mass of the liquid crystal compound.

### ——Chiral Agent (Optically Active Compound)——

The chiral agent has a function of causing a helical structure of a cholesteric liquid crystalline phase to be formed. The chiral agent may be selected depending on the purpose since a helical twisted direction or a helical pitch derived from the compound varies.

The chiral agent is not particularly limited, and a well-known compound (for example, Liquid Crystal Device Handbook (No. 142 Committee of Japan Society for the Promotion of Science, 1989), Chapter 3, Article 4-3, chiral agent for twisted nematic (TN) or super twisted nematic (STN), p. 199), isosorbide, an isomannide derivative, or the like can be used.

The chiral agent generally includes an asymmetric carbon atom, but an axially chiral compound or a planar chiral compound, including no asymmetric carbon atom, can also be used as the chiral agent. Examples of the axially chiral compound or the planar chiral compound include binaphthyl, helicene, paracyclophane, and derivatives thereof. The chiral agent may also have a polymerizable group. In a case where both the chiral agent and the liquid crystal compound have a polymerizable group, a polymer having a repeating unit induced from the polymerizable liquid crystal compound and a repeating unit induced from the chiral agent can be formed by a polymerization reaction between the polymerizable chiral agent and the polymerizable liquid crystal compound. In this aspect, it is preferable that the polymerizable group in the polymerizable chiral agent is the same as the polymerizable group in the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

In a case where the chiral agent has a photoisomerization group, a pattern having a desired reflection wavelength corresponding to a luminescence wavelength can be formed by irradiation of an actinic ray or the like through a photo mask after coating and alignment, which is preferable. As the photoisomerization group, an isomerization portion of a photochromic compound, an azo group, an azoxy group, or a cinnamoyl group is preferable. Specific examples of the compound include compounds described in JP2002-080478A, JP2002-080851A, JP2002-179668A, JP2002-179669A, JP2002-179670A, JP2002-179681A, JP2002-179682A, JP2002-338575A, JP2002-338668A, JP2003-313189A, JP2003-313292A, and the like.

The content of the chiral agent in the liquid crystal composition is preferably 0.01% to 200% by mole, and more preferably 1% to 30% by mole with respect to the molar content of the liquid crystal compound.

### ——Polymerization Initiator——

In a case where the liquid crystal composition includes a polymerizable compound, it is preferable that the liquid crystal composition contains a polymerization initiator. In an aspect where a polymerization reaction progresses with ultraviolet irradiation, it is preferable that the polymerization initiator is a photopolymerization initiator which initiates a polymerization reaction with ultraviolet irradiation.

Examples of the photopolymerization initiator include α-carbonyl compounds (described in the specifications of U.S. Pat. Nos. 2,367,661A and 2,367,670A), acyloin ether (described in the specification of U.S. Pat. No. 2,448,828A), α-hydrocarbon-substituted aromatic acyloin compounds (described in the specification of U.S. Pat. No. 2,722,512A), polynuclear quinone compounds (described in the specifications of U.S. Pat. Nos. 3,046,127A and 2,951,758A), combinations of triarylimidazole dimer and p-aminophenyl ketone (described in the specification of U.S. Pat. No. 3,549,367A), acridine compounds and phenazine compounds (described in JP1985-105667A (JP-S60-105667A) and the specification of U.S. Pat. No. 4,239,850A), and oxadiazole compounds (described in the specification of U.S. Pat. No. 4,212,970A).

A content of the photopolymerization initiator in the liquid crystal composition is preferably 0.1% to 20% by mass, and more preferably 0.5% to 12% by mass with respect to the content of the liquid crystal compound.

### ——Crosslinking Agent——

In order to improve the film hardness after curing and to improve durability, the liquid crystal composition may optionally contain a crosslinking agent. As the crosslinking agent, a crosslinking agent that cures the liquid crystal composition with ultraviolet rays, heat, humidity, and the like can be suitably used.

The crosslinking agent is not particularly limited and can be appropriately selected depending on the purpose. Examples of the crosslinking agent include a polyfunctional acrylate compound such as trimethylol propane tri(meth)acrylate and pentaerythritol tri(meth)acrylate; an epoxy compound such as glycidyl (meth)acrylate and ethylene glycol diglycidyl ether; an aziridine compound such as 2,2-bis hydroxymethyl butanol-tris[3-(1-aziridinyl)propionate] and 4,4-bis(ethyleneiminocarbonylamino)diphenylmethane; an isocyanate compound such as hexamethylene diisocyanate and a biuret type isocyanate; a polyoxazoline compound having an oxazoline group at a side chain thereof; and an alkoxysilane compound such as vinyl trimethoxysilane and N-(2-aminoethyl)-3-aminopropyltrimethoxysilane. In addition, a known catalyst can be used depending on reactivity of the crosslinking agent, and in addition to improving the film hardness and the durability, productivity can be improved. These may be used alone or in combination of two or more kinds thereof.

The content of the crosslinking agent is preferably 3 to 20 mass % and more preferably 5 to 15 mass % with respect to the solid content mass of the liquid crystal composition. In a case where the content of the crosslinking agent is in the above-described range, an effect of improving a crosslinking density can be easily obtained, and the stability of a cholesteric liquid crystalline phase is further improved.

### ——Other Additives——

Optionally, a polymerization inhibitor, an antioxidant, an ultraviolet absorber, a light stabilizer, a coloring material, metal oxide fine particles, or the like can be added to the liquid crystal composition in a range where optical performance and the like do not deteriorate.

In a case where the cholesteric liquid crystal layer is formed, it is preferable that the liquid crystal composition is used as liquid.

The liquid crystal composition may include a solvent. The solvent is not limited and can be appropriately selected depending on the purpose, but an organic solvent is preferable.

The organic solvent is not limited and can be appropriately selected depending on the purpose. Examples of the organic solvent include ketones, alkyl halides, amides, sulfoxides, heterocyclic compounds, hydrocarbons, esters, and ethers. These may be used alone or in combination of two or more kinds thereof. Among these, the ketone is preferable in consideration of an environmental burden.

In a case where the cholesteric liquid crystal layer is formed, it is preferable that the cholesteric liquid crystal layer is formed by applying the liquid crystal composition to a surface where the cholesteric liquid crystal layer is to be formed, aligning the liquid crystal compound to a state of a cholesteric liquid crystalline phase, and curing the liquid crystal compound.

That is, in a case where the cholesteric liquid crystal layer is formed on the alignment film 32 described below, it is preferable that the cholesteric liquid crystal layer obtained by immobilizing a cholesteric liquid crystalline phase is formed by applying the liquid crystal composition to the alignment film 32, aligning the liquid crystal compound to a state of a cholesteric liquid crystalline phase, and curing the liquid crystal compound.

For the application of the liquid crystal composition, a printing method such as ink jet or scroll printing or a well-known method such as spin coating, bar coating, or spray coating capable of uniformly applying liquid to a sheet-like material can be used.

The applied liquid crystal composition is dried and/or heated as necessary, and then is cured to form the cholesteric liquid crystal layer. In the drying and/or heating step, the liquid crystal compound in the liquid crystal composition may be aligned to a cholesteric liquid crystalline phase. In the case of heating, the heating temperature is preferably 200° C. or lower, and more preferably 130° C. or lower.

The aligned liquid crystal compound is further polymerized as necessary. With regard to the polymerization, either of thermal polymerization and photopolymerization using light irradiation may be performed, but the photopolymerization is preferable. Regarding the light irradiation, ultraviolet ray is preferably used. The irradiation energy is preferably 20 mJ/cm² to 50 J/cm², and more preferably 50 to 1,500 mJ/cm². In order to promote a photopolymerization reaction, the light irradiation may be performed under heating conditions or in a nitrogen atmosphere. The wavelength of the ultraviolet rays to be emitted is preferably 250 to 430 nm.

In addition, as a method of forming the cholesteric liquid crystal layer, a method of forming a tilted liquid crystal layer that is formed of a composition including a disk-like liquid crystal compound and in which a molecular axis of the disk-like liquid crystal compound is tilted with respect to the surface and forming a cholesteric liquid crystal layer on the tilted liquid crystal layer using a composition including a liquid crystal compound is suitably used.

The method of forming the cholesteric liquid crystal layer using the tilted liquid crystal layer is described in paragraphs “0049” to “0194” of WO2019/181247A.

The thickness of the cholesteric liquid crystal layer is not particularly limited, and may be appropriately set depending on the use of the liquid crystal diffraction element, the light reflectivity required for the cholesteric liquid crystal layer, the material for forming the cholesteric liquid crystal layer, and the like.

In addition, in the above-described cholesteric liquid crystal layer where the helical pitch changes in the thickness direction, the chiral agent in which back isomerization, dimerization, isomerization and dimerization or the like occurs during light irradiation such that the helical twisting power (HTP) changes is used. By irradiating the liquid crystal composition with light having a wavelength at the HTP of the chiral agent changes before or during the curing of the liquid crystal composition for forming the cholesteric liquid crystal layer, the cholesteric liquid crystal layer having the PG structure can be formed.

For example, by using a chiral agent in which the HTP decreases during light irradiation, the HTP of the chiral agent decreases during light irradiation. Here, the irradiated light is absorbed by a material for forming the cholesteric liquid crystal layer. Accordingly, for example, in a case where the light is irradiated from the upper side, the irradiation dose of the light gradually decreases from the upper side to the lower side. That is, the amount of decrease in the HTP of the chiral agent gradually decreases from above to below. Therefore, on the upper side where the decrease in HTP is large, the induction of helix is small, and thus the helical pitch is long. On the lower side where the decrease in HTP is small, helix is induced by the original HTP of the chiral agent, and thus the helical pitch decreases. As a result, the cholesteric liquid crystal layer where the helical pitch changes in the thickness direction can be formed.

The light irradiation may be performed before or during the exposure for curing the cholesteric liquid crystal layer. In addition, the wavelength of light for changing the HTP of the chiral agent and the wavelength of light for curing the cholesteric liquid crystal layer may be the same as or different from each other.

The image display apparatus according to the embodiment of the present invention has been described above in detail, but the present invention is not limited to the above-described examples, and various improvements and changes may be made without departing from the scope of the present invention.

### EXAMPLES

Hereinafter, the characteristics of the present invention will be described in detail using examples. Materials, chemicals, used amounts, material amounts, ratios, treatment details, treatment procedures, and the like shown in the following examples can be appropriately changed within a range not departing from the scope of the present invention. Therefore, the scope of the present invention should not be construed as being limited to the following specific examples.

### Example 1

### <Preparation of Transmissive Liquid Crystal Diffraction Element>

### [Preparation of Support)

### (Preparation of Core Layer Cellulose Acylate Dope)

The following composition was put into a mixing tank and stirred to dissolve each component, thereby preparing a cellulose acetate solution used as a core layer cellulose acylate dope.

Core layer cellulose acylate dope

| | |
|---|---|
| Cellulose acetate having an acetyl substitution degree | 100 parts by mass |
| of 2.88 | |
| Polyester A | 12 parts by mass |
| Methylene chloride (first solvent) | 430 parts by mass |
| Methanol (second solvent) | 64 parts by mass |

As the polyester A, a polyester A shown in [Table 1] of JP2015-227956A was used.

### (Preparation of Outer Layer Cellulose Acylate Dope)

10 parts by mass of the following matting agent solution was added to 90 parts by mass of the above-described core layer cellulose acylate dope to prepare a cellulose acetate solution as an outer layer cellulose acylate dope.

Matting agent solution

| | | |
|---|---|---|
| Silica particles with average particle size of 20 nm | 2 | parts by mass |
| (AEROSIL R971, manufactured by Nippon Aerosil | | |
| Co., Ltd.) | | |
| Methylene chloride (first solvent) | 76 | parts by mass |
| Methanol (second solvent) | 11 | parts by mass |
| Core layer cellulose acylate dope | 1 | part by mass |

The above-described core layer cellulose acylate dope and the above-described outer layer cellulose acylate dope were filtered through filter paper having an average hole diameter of 34 μm and a sintered metallic filter having an average hole diameter of 10 μm, respectively. Next, three layers of the core layer cellulose acylate dope and the outer layer cellulose acylate dope disposed on opposite sides of the core layer cellulose acylate dope were simultaneously cast on a drum at 20° C. from casting nozzles using a band casting machine.

Next, the obtained film was removed in a state where the solvent content was about 20 mass %, both ends of the film in the width direction were fixed using a tenter clip, and the film was horizontally stretched to a stretching ratio of 1.1% and dried.

Next, by transporting the film between rolls of a heat treatment device and further drying the film, a cellulose support having a thickness of 20 μm was prepared. In the prepared cellulose support, the thickness of the core layer was 15 μm, and the thickness of each of the outer layers disposed on opposite sides of the core layer was 2.5 μm.

### (Saponification Treatment of Support)

The support prepared as described above was caused to pass through a dielectric heating roll at a temperature of 60° C. such that the surface temperature of the support was increased to 40° C.

Next, an alkali solution shown below was applied to a single surface of the support using a bar coater in an application amount of 14 mL (liter)/m², the support was heated to 110° C., and the support was transported for 10 seconds under a steam far infrared heater (manufactured by Noritake Co., Ltd.).

Next, 3 mL/m² of pure water was applied to a surface of the support to which the alkali solution was applied using the same bar coater. Next, water cleaning using a foundry coater and water draining using an air knife were repeated three times, and then the support was transported and dried in a drying zone at 70° C. for 10 seconds. As a result, the alkali saponification treatment was performed on the surface of the support.

Alkaline solution

| | | |
|---|---|---|
| Potassium hydroxide | 4.70 | parts by mass |
| Water | 15.80 | parts by mass |
| Isopropanol | 63.70 | parts by mass |
| Surfactant | 1.0 | part by mass |
| SF-1: C₁₄H₂₉O(CH₂CH₂O)₂OH | | |
| Propylene glycol | 14.8 | parts by mass |

### Formation of Undercoat Layer

The following coating liquid for forming an undercoat layer was continuously applied onto a surface of the support which had been subjected to an alkali saponification treatment using a #8 wire bar. The support on which the coating film had been formed was dried using hot air at 60° C. for 60 seconds and further dried using hot air at 100° C. for 120 seconds to form an undercoat layer.

Coating liquid for forming undercoat layer

| | |
|---|---|
| The following modified polyvinyl alcohol | 2.40 parts by mass |
| Isopropyl alcohol | 1.60 parts by mass |
| Methanol | 36.00 parts by mass |
| Water | 60.00 parts by mass |

modified polyvinyl alcohol

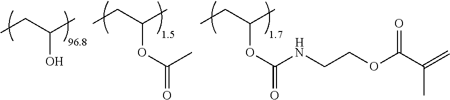

### (Formation of Alignment Film)

The following alignment film-forming coating liquid was continuously applied to the support on which the undercoat layer was formed using a #2 wire bar. The support on which the coating film of the coating liquid for forming an alignment film had been formed was dried using a hot plate at 60° C. for 60 seconds to form an alignment film.

Coating Liquid for Forming Alignment Film

| | |
|---|---|
| Material A for photo-alignment | 1.00 part by mass |
| Water | 16.00 parts by mass |
| Butoxyethanol | 42.00 parts by mass |
| Propylene glycol monomethyl ether | 42.00 parts by mass |

-Material A for Photo-Alignment-

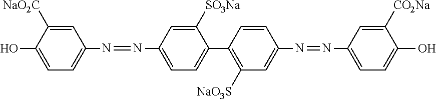

### (Exposure of Alignment Film)

The alignment film was exposed using the exposure device shown in FIG. 18 to form an alignment film P-1 having an alignment pattern.

In the exposure device, a laser that emits laser light having a wavelength (325 nm) was used as the laser. The exposure amount of the interference light was 100 mJ/cm². The intersecting angle (intersecting angle α) between the two laser light beams was adjusted such that the single period Λ (the length over which the optical axis derived from the liquid crystal compound rotated by) 180° of the alignment pattern formed by the interference of the two laser light beams was 1 μm.

### (Formation of Optically Anisotropic Layer)

As the liquid crystal composition for forming the optically anisotropic layer, the following composition A-1 was prepared.

Composition A-1

| | |
|---|---|
| Liquid crystal compound L-1 | 100.00 parts by mass |
| Polymerization initiator (IRGACURE (registered trade name) 907, manufactured by BASF SE) | 3.00 parts by mass |
| Photosensitizer (KAYACURE DETX-S, manufactured by Nippon Kayaku Co., Ltd.) | 1.00 part by mass |
| Leveling agent T-1 | 0.24 parts by mass |
| Methyl ethyl ketone | 1087.80 parts by mass |

Liquid crystal compound L-1 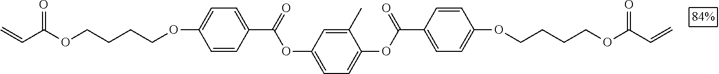 [SMILES: C=CC(=O)OCCCCOc1ccc(C(=O)Oc2ccc(OC(=O)c3ccc(OCCCCOC(=O)C=C)cc3)c(C)c2)cc1] 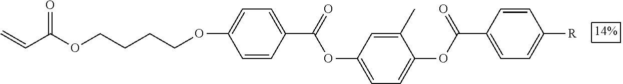 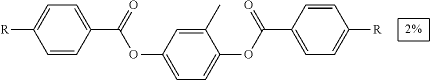 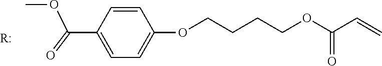
Leveling agent T-1

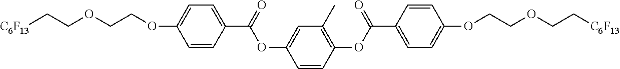

The optically anisotropic layer was formed by applying multiple layers of the composition A-1 to the alignment film P-1. The application of the multiple layers refers to repetition of the following processes including: preparing a first liquid crystal immobilized layer by applying the composition A-1 for forming the first layer to the alignment film, heating the composition A-1, cooling the composition A-1, and irradiating the composition A-1 with ultraviolet light for curing; and preparing a second or subsequent liquid crystal immobilized layer by applying the composition A-1 for forming the second or subsequent layer to the formed liquid crystal immobilized layer, heating the composition A-1, cooling the composition A-1, and irradiating the composition A-1 with ultraviolet light for curing as described above. Even in a case where the liquid crystal layer was formed by the application of the multiple layers such that the total thickness of the liquid crystal layer was large, the alignment direction of the alignment film was reflected from a lower surface of the liquid crystal layer to an upper surface thereof.

Regarding the first liquid crystal layer, the following composition A-1 was applied to the alignment film P-1 to form a coating film, the coating film was heated using a hot plate at 70° C., the coating film was cooled to 25° C., and the coating film was irradiated with ultraviolet light having a wavelength of 365 nm at an irradiation dose of 100 mJ/cm² using a high-pressure mercury lamp in a nitrogen atmosphere. As a result, the alignment of the liquid crystal compound was immobilized. In this case, the thickness of the first liquid crystal layer was 0.2 μm.

Regarding the second or subsequent liquid crystal layer, the composition was applied to the first liquid crystal layer, and the applied composition was heated, cooled, and irradiated with ultraviolet light for curing under the same conditions as described above. As a result, a liquid crystal immobilized layer was prepared. This way, by repeating the application multiple times until the total thickness reached a desired film thickness, an optically anisotropic layer was obtained, and a transmissive liquid crystal diffraction element was prepared.

The Δn_{λ} of optically anisotropic layer×the thickness (Re(λ)) was obtained by applying the composition A1 to a support with an alignment film for retardation measurement that was prepared separately, aligning the director of the liquid crystal compound to be parallel to the substrate, irradiating the liquid crystal compound with ultraviolet irradiation for immobilization to obtain a liquid crystal immobilized layer (cured layer), and measuring the retardation value of the liquid crystal immobilized layer. The retardation value at a desired wavelength was appropriately measured using Axoscan (manufactured by Axometrics, Inc.).

It was confirmed with a polarization microscope that the optically anisotropic layer finally had Δn₅₃₀ of liquid crystal×thickness (Re(530)) of 265 nm and had a periodically aligned surface as shown in FIG. 13. In the liquid crystal alignment pattern of the optically anisotropic layer, the single period over which the optical axis derived from the liquid crystal compound rotated by 180° was 1 μm.

### <Preparation of Image Display Apparatus>

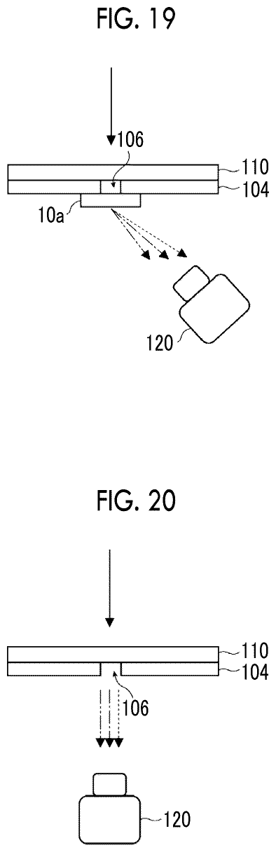

Next, the OLED panel was disassembled from Galaxy Z Fold2 (manufactured by Samsung Electronics Co., Ltd.), and the prepared transmissive liquid crystal diffraction element 10a was disposed below a location (transmission unit 106) to which the sensor of the image display panel 104 was attached. In addition, a spectroradiometer (SR-UL1R, manufactured by Topcon Corporation) 120 was disposed as a light detection unit in a direction in which the vertically incident ambient light is diffracted by the transmissive liquid crystal diffraction element 10a, and an image display apparatus was prepared. FIG. 19 conceptually shows a configuration of the image display apparatus. The circularly polarizing plate 110 is laminated on the image display panel 104, and the ambient light transmitted through the transmission unit 106 is converted into circularly polarized light and is incident into the transmissive liquid crystal diffraction element 10a.

### Comparative Example 1

An image display apparatus was prepared using the same method as that of Example 1, except that the transmissive liquid crystal diffraction element of Example 1 was removed and the spectroradiometer was disposed as shown in FIG. 20.

### Comparative Example 2

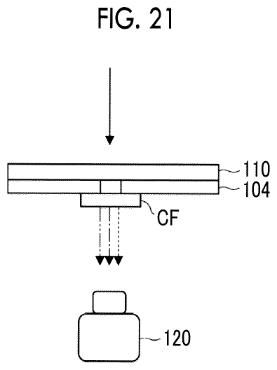

An image display apparatus was prepared using the same method as that of Example 1, except that the color filter CF was disposed instead of the transmissive liquid crystal diffraction element of Example 1 and the spectroradiometer was disposed as shown in FIG. 21.

### [Evaluation]

A full-color LED (model number: OSTCXBTHCIE, manufactured by Opto Supply, Inc.) was disposed as ambient light at a distance of 20 cm from the display surface of the image display panel. In a case where any of RGB of the full-color LEDs was turned on and the image display panel was black (turned off) and white, the X, Y (luminance value, [cd/m²]) and Z of three stimulus values in the CIE 1031 color space were measured in the configurations of Examples and Comparative Examples, respectively.

Here, in Example 1, the position of the spectroradiometer was adjusted to a position where the light amount was maximum for each color in which the full-color LED was turned on.

In addition, in Comparative Example 2, each of the three stimulus values X/Y/Z was measured by changing the color of the color filter as follows.
Measurement of X: Color filter R (color correction filters CC-40R and CC-20R, manufactured by FUJIFILM Corporation) were disposed.
Measurement of Y: Color filter G (color correction filters CC-40G and CC-20G, manufactured by FUJIFILM Corporation) were disposed.
Measurement of Z: Color filter B (color correction filters CC-40B and CC-20B, manufactured by FUJIFILM Corporation) were disposed.

In addition, as a reference example, the full-color LEDs were turned on to directly measure X, Y, and Z with a spectroradiometer.

The measurement results are shown in Table 1.

TABLE 1

| | | Ambient light | | | | | | | | |
|---|---|---|---|---|---|---|---|---|---|---|
| | OLED | Turning on B-LED | | | Turning on G-LED | | | Turning on R-LED | | |
| | panel | X | Y | Z | X | Y | Z | X | Y | Z |
| Example 1 | Black | 15 | 9 | 92 | 13 | 81 | 9 | 66 | 31 | 1 |
| | display | | | | | | | | | |
| | White | 17 | 11 | 94 | 15 | 83 | 11 | 68 | 33 | 3 |
| | display | | | | | | | | | |
| Comparative | Black | 16 | 10 | 93 | 11 | 62 | 8 | 34 | 17 | 2 |
| Example 1 | display | | | | | | | | | |
| | White | 196 | 208 | 356 | 190 | 260 | 271 | 214 | 215 | 265 |
| | display | | | | | | | | | |
| Comparative | Black | 16 | 10 | 30 | 11 | 26 | 8 | 14 | 17 | 2 |
| Example 2 | display | | | | | | | | | |
| | White | 23 | 16 | 115 | 34 | 110 | 14 | 88 | 45 | 15 |
| | display | | | | | | | | | |
| Reference | Only | 15 | 8 | 91 | 12 | 80 | 8 | 66 | 30 | 1 |
| Example | ambient | | | | | | | | | |
| | light | | | | | | | | | |
| | (full- | | | | | | | | | |
| | color | | | | | | | | | |
| | LED) | | | | | | | | | |

In Example 1, a value close to the three stimulus values measured only with the ambient light (reference example) is obtained, whereas in Comparative Examples 1 and 2, it can be seen that the values are significantly different particularly in a case of white display. This is because the light emitted from the image display panel is reflected by the interface or the like and is detected by the spectroradiometer. From this, it can be seen that the tint of the ambient light can be measured with high accuracy in the configuration of Example 1.

In addition, in Comparative Example 1, since the ambient light cannot be separated for each wavelength, the amount of light for each wavelength cannot be measured. In addition, in Comparative Example 2, it is possible to separate and detect ambient light for each wavelength by using the color filter, but since the amount of light at each wavelength is small, it is difficult to accurately measure the amount of light at each wavelength. On the other hand, in Example 1, it can be seen that, since the ambient light is diffracted at different angles for each wavelength, the amount of light at each wavelength can be accurately measured.

The effects of the present invention are obvious from the above results.

The present invention can be suitably used for various devices having an image display apparatus such as a mobile device such as a smartphone and a tablet terminal, a laptop computer, a PC monitor, and a television.

### EXPLANATION OF REFERENCES

10a: transmissive diffraction grating
10b: reflective diffraction grating
12: light guide plate
14: emission-side diffraction grating
20, 20a to 20h: light detection unit
22a to 22f: photoelectric conversion element
23: line sensor
24, 26: support member
30: support
32: alignment film
34: cholesteric liquid crystal layer
36: optically anisotropic layer
40: liquid crystal compound
40A: optical axis
60: exposure device
62: laser
64: light source
65: λ/2 plate
68: beam splitter
70A, 70B: mirror
72A, 72B: λ/4 plate
100: image display apparatus
102: housing
104: image display panel
104a: display surface
106: transmission unit
110a to 110j: ambient light sensor system
120: spectroradiometer
122: circularly polarizing plate
A: single period
D: arrangement axis
L₁, L₄: incidence rays
L₂, L₅: emitted light
R_{R}: dextrorotatory circularly polarized light
α: intersecting angle
M: laser light
MA, MB: beam
P₀: linearly polarized light
P_{R}: dextrorotatory circularly polarized light
P_{L}: levorotatory circularly polarized light

What is claimed is:

1. An image display apparatus comprising:
an image display panel; and
an ambient light sensor system,
wherein the image display panel includes a transmission unit that allows ambient light to pass through in a display region,
the ambient light sensor system includes
a diffraction grating that diffracts light of each wavelength component at different angles according to a wavelength of the ambient light that has passed through the transmission unit, and
a light detection unit that receives the light diffracted by the diffraction grating.

2. The image display apparatus according to claim 1,
wherein the ambient light sensor system further includes a light guide plate.

3. The image display apparatus according to claim 2,
wherein the diffraction grating includes an incidence-side diffraction grating for light incidence on the light guide plate and an emission-side diffraction grating for light emission from the light guide plate.

4. The image display apparatus according to claim 1,
wherein the diffraction grating is a transmissive diffraction grating.

5. The image display apparatus according to claim 1,
wherein the diffraction grating is a reflective diffraction grating.

6. The image display apparatus according to claim 1,
wherein the diffraction grating is any one of a liquid crystal diffraction element, a surface relief type diffraction element, or a metasurface.

7. The image display apparatus according to claim 1,
wherein the light detection unit has a plurality of photoelectric conversion elements arranged, and each photoelectric conversion element detects an amount of light of each wavelength component diffracted at different angles.

8. The image display apparatus according to claim 1,
wherein the light detection unit includes a line sensor, and
each pixel of the line sensor detects an amount of light of each wavelength component diffracted at different angles.

9. The image display apparatus according to claim 1, further comprising:
at least one of a lens, a prism, a louver, a phase difference plate, or an anisotropic light absorbing layer that is disposed on the transmission unit or at least one of the transmission unit or the diffraction grating.

10. The image display apparatus according to claim 2,
wherein the diffraction grating is a transmissive diffraction grating.

11. The image display apparatus according to claim 2,
wherein the diffraction grating is a reflective diffraction grating.

12. The image display apparatus according to claim 2,
wherein the diffraction grating is any one of a liquid crystal diffraction element, a surface relief type diffraction element, or a metasurface.

13. The image display apparatus according to claim 2,
wherein the light detection unit has a plurality of photoelectric conversion elements arranged, and each photoelectric conversion element detects an amount of light of each wavelength component diffracted at different angles.

14. The image display apparatus according to claim 2,
wherein the light detection unit includes a line sensor, and
each pixel of the line sensor detects an amount of light of each wavelength component diffracted at different angles.

15. The image display apparatus according to claim 2, further comprising:
at least one of a lens, a prism, a louver, a phase difference plate, or an anisotropic light absorbing layer that is disposed on the transmission unit or at least one of the transmission unit or the diffraction grating.

16. The image display apparatus according to claim 3,
wherein the diffraction grating is a transmissive diffraction grating.

17. The image display apparatus according to claim 3,
wherein the diffraction grating is a reflective diffraction grating.

18. The image display apparatus according to claim 3,
wherein the diffraction grating is any one of a liquid crystal diffraction element, a surface relief type diffraction element, or a metasurface.

19. The image display apparatus according to claim 3,
wherein the light detection unit has a plurality of photoelectric conversion elements arranged, and each photoelectric conversion element detects an amount of light of each wavelength component diffracted at different angles.

20. The image display apparatus according to claim 3,
wherein the light detection unit includes a line sensor, and
each pixel of the line sensor detects an amount of light of each wavelength component diffracted at different angles.

21. The image display apparatus according to claim 3, further comprising:
at least one of a lens, a prism, a louver, a phase difference plate, or an anisotropic light absorbing layer that is disposed on the transmission unit or at least one of the transmission unit or the diffraction grating.
